(19) United States
(12) Patent Application Publication
(10) Pub. No.: US 2024/0112932 A1
(43) Pub. Date: Apr. 4, 2024

(54) MANUFACTURING DEVICE OF DISPLAY DEVICE

(71) Applicant: Japan Display Inc., Tokyo (JP)

(72) Inventors: Takanobu TAKENAKA, Tokyo (JP); Hirofumi MIZUKOSHI, Tokyo (JP); Masaru TAKAYAMA, Tokyo (JP); Yuki HAMADA, Tokyo (JP)

(73) Assignee: Japan Display Inc., Tokyo (JP)

(21) Appl. No.: 18/476,341

(22) Filed: Sep. 28, 2023

(30) Foreign Application Priority Data
Sep. 29, 2022 (JP) 2022-156210

(51) Int. Cl. H01L 21/67; C23C 14/12; C23C 14/24; C23C 14/56; C23C 14/58; H01L 21/677; H10K 59/12; H10K 71/16

(52) U.S. Cl. CPC H01L 21/67173; C23C 14/12; C23C 14/24; C23C 14/568; C23C 14/5806; C23C 14/5873; H01L 21/67748; H10K 59/1201; H10K 71/16

(57) ABSTRACT

According to one embodiment, a manufacturing device of a display device includes a conveyance mechanism for conveying a processing substrate in a first direction, and first, second, third and fourth evaporation portions arranged in order in the first direction. The first evaporation portion includes a plurality of evaporation chambers for forming an organic layer. The second evaporation portion includes an evaporation chamber for forming an upper electrode. The third evaporation portion includes an evaporation chamber for forming a first transparent layer. The fourth evaporation portion includes an evaporation chamber for forming a second transparent layer having a refractive index less than a refractive index of the first transparent layer on the first transparent layer.

### CROSS-REFERENCE TO RELATED APPLICATIONS

This application is based upon and claims the benefit of priority from Japanese Patent Application No. 2022-156210, filed Sep. 29, 2022, the entire contents of which are incorporated herein by reference.

### FIELD

Embodiments described herein relate generally to a manufacturing device of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In manufacturing devices for forming the display elements, the prevention of the reduction in the production efficiency is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram showing an example of the configuration of display elements 201 to 203.

FIG. 5 is a diagram showing another example of the configuration of the display elements 201 to 203.

FIG. 6 is a flow diagram for explaining an example of the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a diagram for explaining the manufacturing method of the display device DSP.

FIG. 17 is a diagram for explaining the manufacturing method of the display device DSP.

FIG. 18 is a diagram for explaining the manufacturing method of the display device DSP.

FIG. 19 is a diagram for explaining a configuration example of a manufacturing device 100.

FIG. 20 is a cross-sectional view showing a configuration example of a typical evaporation chamber 121.

FIG. 21 is a diagram showing a configuration example of a manufacturing system 300 comprising the manufacturing device 100 shown in FIG. 19.

FIG. 22 is a diagram for explaining another configuration example of the manufacturing device 100.

### DETAILED DESCRIPTION

Embodiments described herein aim to provide a manufacturing device of a display device such that the reduction in the production efficiency can be prevented.

In general, according to one embodiment, a manufacturing device of a display device comprises a conveyance mechanism for conveying a processing substrate in a first direction, the processing substrate comprising a lower electrode located above a substrate, a rib comprising an aperture overlapping the lower electrode, and a partition which includes a lower portion located on the rib and an upper portion located on the lower portion and protruding from a side surface of the lower portion, a preprocessing portion which is connected to an upstream side in the first direction of the conveyance mechanism and performs preprocessing for the processing substrate, a post-processing portion which is connected to a downstream side in the first direction of the conveyance mechanism and performs post-processing for the processing substrate, and first, second, third and fourth evaporation portions arranged in order in the first direction of the conveyance mechanism. The first evaporation portion comprises a plurality of evaporation chambers for forming an organic layer on the lower electrode in the aperture. The second evaporation portion comprises an evaporation chamber for forming an upper electrode on the organic layer. The third evaporation portion comprises an evaporation chamber for forming a first transparent layer on the upper electrode. The fourth evaporation portion comprises an evaporation chamber for forming a second transparent layer having a refractive index less than a refractive index of the first transparent layer on the first transparent layer.

According to another embodiment, a manufacturing device of a display device comprises a conveyance mechanism for conveying a processing substrate comprising a lower electrode in a first direction, a preprocessing portion which is connected to an upstream side in the first direction of the conveyance mechanism and performs preprocessing for the processing substrate, a post-processing portion which is connected to a downstream side in the first direction of the conveyance mechanism and performs post-processing for the processing substrate, and a plurality of evaporation chambers arranged in order in the first direction of the conveyance mechanism. The preprocessing portion comprises a securing portion which secures the processing substrate to a carrier. The post-processing portion comprises a detachment portion which detaches the processing substrate from the carrier. The securing portion is adjacent to, of the plurality of evaporation chambers, the evaporation chamber located at an end of the upstream side in the first direction. The detachment portion is adjacent to, of the plurality of evaporation chambers, the evaporation chamber located at an end of the downstream side in the first direction.

According to yet another embodiment, a manufacturing device of a display device comprises a conveyance mechanism for conveying a processing substrate comprising a lower electrode in a first direction, a preprocessing portion which is connected to an upstream side in the first direction of the conveyance mechanism and performs preprocessing for the processing substrate, a post-processing portion which is connected to a downstream side in the first direction of the conveyance mechanism and performs post-processing for the processing substrate, and a plurality of evaporation chambers arranged in order in the first direction of the conveyance mechanism. The preprocessing portion comprises a securing portion which secures the processing substrate to a carrier. The post-processing portion comprises a detachment portion which detaches the processing substrate from the carrier. The plurality of evaporation chambers comprise, between the securing portion and the detachment portion, an evaporation chamber for forming a first light emitting layer, an evaporation chamber for forming a second light emitting layer which emits light having a wavelength different from a wavelength of the first light emitting layer, and an evaporation chamber for forming a third light emitting layer which emits light having a wavelength different from the wavelengths of the first light emitting layer and the second light emitting layer.

The embodiment can provide a manufacturing device of a display device such that the reduction in the production efficiency can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

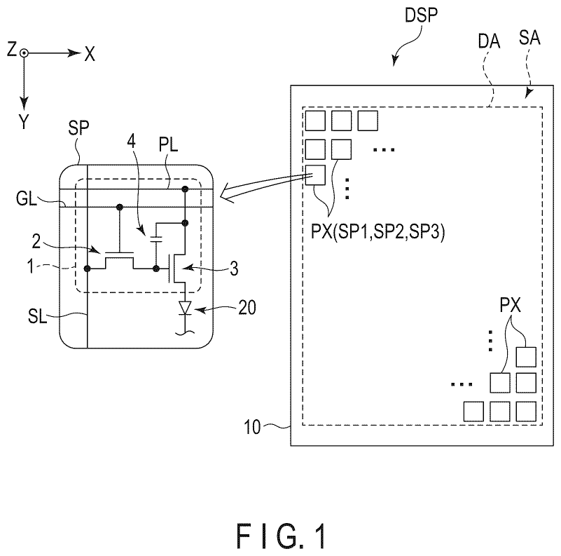

FIG. 1 is a diagram showing a configuration example of a display device DSP.

The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

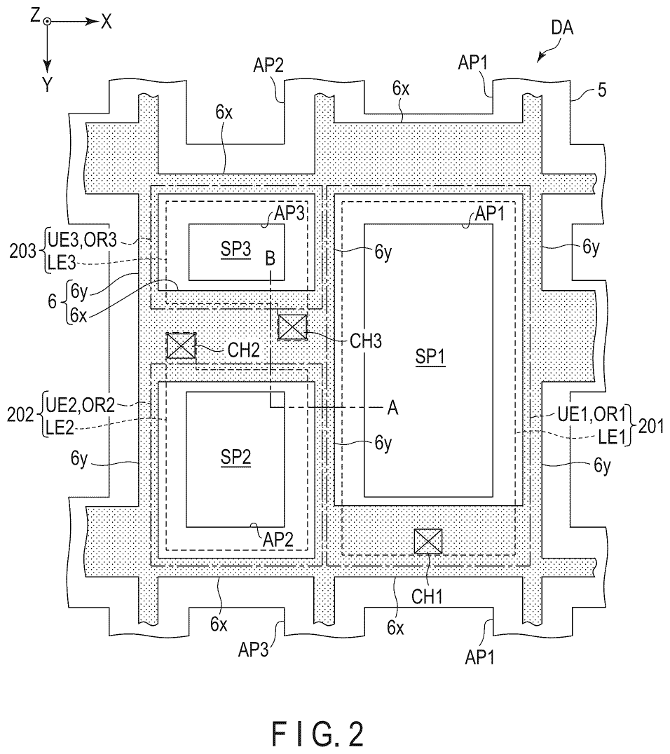

Although not described in detail, a terminal for connecting an IC chip and a flexible printed circuit is provided in the surrounding area SA. FIG. 2 is a diagram showing an example of the layout of subpixels SP1, SP2 and SP3.

In the example of FIG. 2, subpixels SP2 and SP3 are arranged in the second direction Y. Further, each of subpixels SP2 and SP3 is adjacent to subpixel SP1 in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 as seen in plan view. The partition 6 comprises a plurality of first partitions 6x extending in the first direction X and a plurality of second partitions 6y extending in the second direction Y. The first partitions 6x are provided between the apertures AP2 and AP3 which are adjacent to each other in the second direction Y and between two apertures AP1 which are adjacent to each other in the second direction Y. Each second partition 6y is provided between the apertures AP1 and AP2 which are adjacent to each other in the first direction X and between the apertures AP1 and AP3 which are adjacent to each other in the first direction X.

In the example of FIG. 2, the first partitions 6x and the second partitions 6y are connected to each other. Thus, the partition 6 is formed into a grating shape surrounding the apertures AP1, AP2 and AP3 as a whole. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

Subpixel SP1 comprises a lower electrode LE1, an upper electrode UE1 and an organic layer OR1 overlapping the aperture AP1. Subpixel SP2 comprises a lower electrode LE2, an upper electrode UE2 and an organic layer OR2 overlapping the aperture AP2. Subpixel SP3 comprises a lower electrode LE3, an upper electrode UE3 and an organic layer OR3 overlapping the aperture AP3.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. The peripheral portion of each of the lower electrodes LE1, LE2 and LE3 overlaps the rib 5. It should be noted that the outer shape of each of the lower electrodes, organic layers and upper electrodes shown in the figure does not necessarily reflect the accurate shape.

The lower electrode LE1, the upper electrode UE1 and the organic layer OR1 constitute the display element 201 of subpixel SP1. The lower electrode LE2, the upper electrode UE2 and the organic layer OR2 constitute the display element 202 of subpixel SP2. The lower electrode LE3, the upper electrode UE3 and the organic layer OR3 constitute the display element 203 of subpixel SP3.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

For example, the display element 201 of subpixel SP1 is configured to emit light in a blue wavelength range. The display element 202 of subpixel SP2 is configured to emit light in a green wavelength range. The display element 203 of subpixel SP3 is configured to emit light in a red wavelength range.

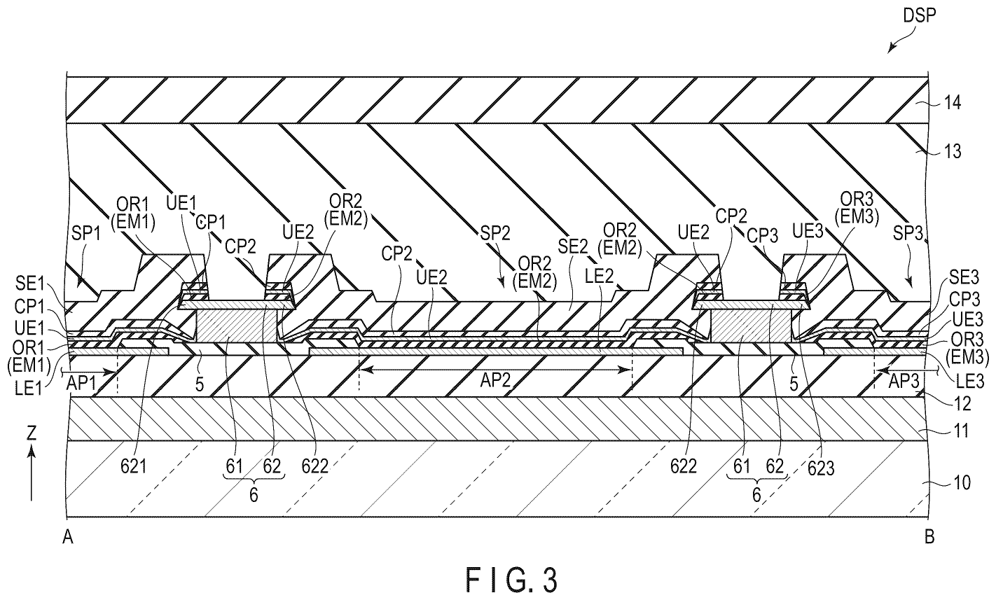

FIG. 3 is a schematic cross-sectional view of the display device DSP along the A-B line of FIG. 2. A circuit layer 11 is provided on the substrate 10 described above. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 functions as a planarization film which planarizes the irregularities formed by the circuit layer 11.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5. In other words, the end portions of the lower electrodes LE1, LE2 and LE3 are provided between the insulating layer 12 and the rib 5. Between, of the lower electrodes LE1, LE2 and LE3, the lower electrodes which are adjacent to each other, the insulating layer 12 is covered with the rib 5.

The partition 6 includes a lower portion (stem) 61 provided on the rib 5 and an upper portion (hat) 62 provided on the lower portion 61. The lower portion 61 of the partition 6 shown on the left side of the figure is located between the aperture AP1 and the aperture AP2. The lower portion 61 of the partition 6 shown on the right side of the figure is located between the aperture AP2 and the aperture AP3. The upper portion 62 has a width greater than that of the lower portion 61. By this configuration, the both end portions of the upper portion 62 protrude relative to the side surfaces of the lower portion 61. This shape of the partition 6 may be called an overhang shape. Of the upper portion 62, a portion which protrudes to the aperture AP1 relative to the lower portion 61 is referred to as a protrusion 621. A portion which protrudes to the aperture AP2 relative to the lower portion 61 is referred to as a protrusion 622. A portion which protrudes to the aperture AP3 relative to the lower portion 61 is referred to as a protrusion 623.

The organic layer OR1 is in contact with the lower electrode LE1 through the aperture AP1, covers the lower electrode LE1 and overlaps part of the rib 5. The upper electrode UE1 faces the lower electrode LE1 and is provided on the organic layer OR1. Further, the upper electrode UE1 is in contact with a side surface of the lower portion 61. The organic layer OR1 and the upper electrode UE1 are located on the lower side relative to the upper portion 62.

The organic layer OR2 is in contact with the lower electrode LE2 through the aperture AP2, covers the lower electrode LE2 and overlaps part of the rib 5. The upper electrode UE2 faces the lower electrode LE2 and is provided on the organic layer OR2. Further, the upper electrode UE2 is in contact with a side surface of the lower portion 61. The organic layer OR2 and the upper electrode UE2 are located on the lower side relative to the upper portion 62.

The organic layer OR3 is in contact with the lower electrode LE3 through the aperture AP3, covers the lower electrode LE3 and overlaps part of the rib 5. The upper electrode UE3 faces the lower electrode LE3 and is provided on the organic layer OR3. Further, the upper electrode UE3 is in contact with a side surface of the lower portion 61. The organic layer OR3 and the upper electrode UE3 are located on the lower side relative to the upper portion 62.

Subpixels SP1, SP2 and SP3 further include cap layers (optical adjustment layers) CP1, CP2 and CP3 for adjusting the optical property of the light emitted from the light emitting layers of the organic layers OR1, OR2 and OR3.

The cap layer CP1 is located in the aperture AP1, is located on the lower side relative to the upper portion 62 and is provided on the upper electrode UE1. The cap layer CP2 is located in the aperture AP2, is located on the lower side relative to the upper portion 62 and is provided on the upper electrode UE2. The cap layer CP3 is located in the aperture AP3, is located on the lower side relative to the upper portion 62 and is provided on the upper electrode UE3.

Sealing layers SE1, SE2 and SE3 are provided in subpixels SP1, SP2 and SP3, respectively.

The sealing layer SE1 is in contact with the cap layer CP1 and the lower and upper portions 61 and 62 of the partition 6 and continuously covers the members of subpixel SP1. The sealing layer SE2 is in contact with the cap layer CP2 and the lower and upper portions 61 and 62 of the partition 6 and continuously covers the members of subpixel SP2. The sealing layer SE3 is in contact with the cap layer CP3 and the lower and upper portions 61 and 62 of the partition 6 and continuously covers the members of subpixel SP3.

The sealing layers SE1, SE2 and SE3 are covered with a protective layer 13. The protective layer 13 is covered with a sealing layer 14.

In the example shown in the figure, part of the organic layer OR1, part of the upper electrode UE1 and part of the cap layer CP1 are located between the partition 6 and the sealing layer SE1, are provided on the upper portion 62 and are spaced apart from the portions located on the lower side relative to the upper portion 62.

Part of the organic layer OR2, part of the upper electrode UE2 and part of the cap layer CP2 are located between the partition 6 and the sealing layer SE2, are provided on the upper portion 62 and are spaced apart from the portions located on the lower side relative to the upper portion 62.

Part of the organic layer OR3, part of the upper electrode UE3 and part of the cap layer CP3 are located between the partition 6 and the sealing layer SE3, are provided on the upper portion 62 and are spaced apart from the portions located on the lower side relative to the upper portion 62.

The insulating layer 12 is an organic insulating layer. The rib 5 and the sealing layers SE1, SE2 and SE3 are inorganic insulating layers.

The rib 5 is formed of silicon nitride (SiNx) as an example of inorganic insulating materials. It should be noted that the rib 5 may be formed of, as another inorganic insulating material, a single-layer body of one of silicon oxide (SiOx), silicon oxynitride (SiON) and aluminum oxide (Al₂O₃). The rib 5 may be formed of a stacked layer body of a combination consisting of at least two of a silicon nitride layer, a silicon oxide layer, a silicon oxynitride layer and an aluminum oxide layer.

The sealing layers SE1, SE2 and SE3 are formed of, for example, the same inorganic insulating material.

The sealing layers SE1, SE2 and SE3 are formed of silicon nitride (SiNx) as an example of inorganic insulating materials. It should be noted that each of the sealing layers SE1, SE2 and SE3 may be formed of, as another inorganic insulating material, a single-layer body of one of silicon oxide (SiOx), silicon oxynitride (SiON) and aluminum oxide (Al₂O₃). Each of the sealing layers SE1, SE2 and SE3 may be formed of a stacked layer body of a combination consisting of at least two of a silicon nitride layer, a silicon oxide layer, a silicon oxynitride layer and an aluminum oxide layer. Thus, each of the sealing layers SE1, SE2 and SE3 may be formed of the same material as the rib 5.

The lower portion 61 of the partition 6 is formed of a conductive material and is electrically connected to the upper electrodes UE1, UE2 and UE3. Both the lower portion 61 and the upper portion 62 of the partition 6 may be formed of conductive materials.

The thickness of the rib 5 is sufficiently less than the thicknesses of the partition 6 and the insulating layer 12. For example, the thickness of the rib 5 is greater than or equal to 200 nm but less than or equal to 400 nm.

The thickness of the lower portion 61 of the partition 6 (the thickness from the upper surface of the rib 5 to the lower surface of the upper portion 62) is greater than that of the rib 5.

The thickness of the sealing layer SE1, the thickness of the sealing layer SE2 and the thickness of the sealing layer SE3 are substantially equal to each other and are, for example, approximately 1 μm.

Each of the lower electrodes LE1, LE2 and LE3 may be formed of a transparent conductive material such as ITO or may comprise a multilayer structure of a metal material such as silver (Ag) and a transparent conductive material. Each of the upper electrodes UE1, UE2 and UE3 is formed of, for example, a metal material such as an alloy of magnesium and silver (MgAg). Each of the upper electrodes UE1, UE2 and UE3 may be formed of a transparent conductive material such as ITO.

Each of the organic layers OR1, OR2 and OR3 includes a plurality of functional layers such as a hole injection layer, a hole transport layer, an electron blocking layer, a hole blocking layer, an electron transport layer and an electron injection layer. The organic layer OR1 includes a light emitting layer EM1. The organic layer OR2 includes a light emitting layer EM2. The light emitting layer EM2 is formed of a material different from that of the light emitting layer EM1. The organic layer OR3 includes a light emitting layer EM3. The light emitting layer EM3 is formed of a material different from the materials of the light emitting layers EM1 and EM2.

The material of the light emitting layer EM1, the material of the light emitting layer EM2 and the material of the light emitting layer EM3 are materials which emit light in different wavelength ranges.

For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the cap layers CP1, CP2 and CP3 is formed of, for example, a multilayer body of transparent thin films. As the thin films, the multilayer body includes a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3.

The protective layer 13 is a transparent organic insulating layer. The sealing layer 14 is a transparent inorganic insulating layer. The sealing layer 14 is formed of silicon nitride (SiNx) as an example of inorganic insulating materials.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the lower electrode LE1 and the upper electrode UE1, the light emitting layer EM1 of the organic layer OR1 emits light in a blue wavelength range. When a potential difference is formed between the lower electrode LE2 and the upper electrode UE2, the light emitting layer EM2 of the organic layer OR2 emits light in a green wavelength range. When a potential difference is formed between the lower electrode LE3 and the upper electrode UE3, the light emitting layer EM3 of the organic layer OR3 emits light in a red wavelength range.

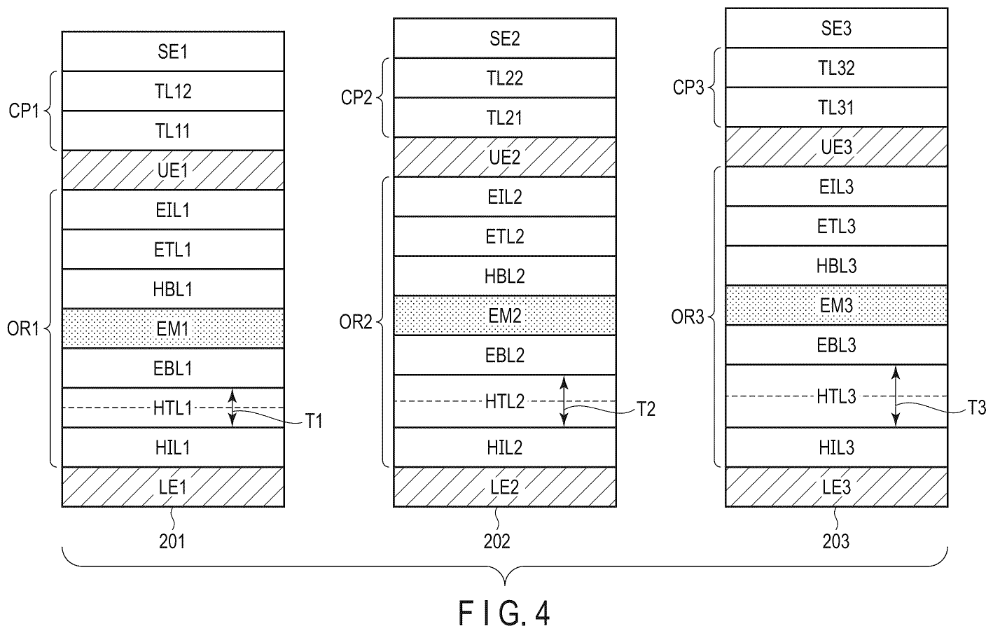

FIG. 4 is a diagram showing an example of the configuration of the display elements 201 to 203.

Here, in the example, this specification explains a case where each lower electrode corresponds to an anode and each upper electrode corresponds to a cathode.

The display element 201 includes the organic layer OR1 between the lower electrode LE1 and the upper electrode UE1.

In the organic layer OR1, a hole injection layer HIL1, a hole transport layer HTL1, an electron blocking layer EBL1, the light emitting layer EM1, a hole blocking layer HBL1, an electron transport layer ETL1 and an electron injection layer EIL1 are stacked in this order.

The cap layer CP1 includes a first transparent layer TL11 and a second transparent layer TL12. The first transparent layer TL11 is provided on the upper electrode UE1. The second transparent layer TL12 is provided on the first transparent layer TL11. The sealing layer SE1 is provided on the second transparent layer TL12.

The display element 202 includes the organic layer OR2 between the lower electrode LE2 and the upper electrode UE2.

In the organic layer OR2, a hole injection layer HIL2, a hole transport layer HTL2, an electron blocking layer EBL2, the light emitting layer EM2, a hole blocking layer HBL2, an electron transport layer ETL2 and an electron injection layer EIL2 are stacked in this order. For example, thickness T2 of the hole transport layer HTL2 is greater than thickness T1 of the hole transport layer HTL1.

The cap layer CP2 includes a first transparent layer TL21 and a second transparent layer TL22. The first transparent layer TL21 is provided on the upper electrode UE2. The second transparent layer TL22 is provided on the first transparent layer TL21. The sealing layer SE2 is provided on the second transparent layer TL22.

The display element 203 includes the organic layer OR3 between the lower electrode LE3 and the upper electrode UE3.

In the organic layer OR3, a hole injection layer HIL3, a hole transport layer HTL3, an electron blocking layer EBL3, the light emitting layer EM3, a hole blocking layer HBL3, an electron transport layer ETL3 and an electron injection layer EIL3 are stacked in this order. For example, thickness T3 of the hole transport layer HTL3 is greater than thickness T2 of the hole transport layer HTL2.

The cap layer CP3 includes a first transparent layer TL31 and a second transparent layer TL32. The first transparent layer TL31 is provided on the upper electrode UE3. The second transparent layer TL32 is provided on the first transparent layer TL31. The sealing layer SE3 is provided on the second transparent layer TL32.

The first transparent layers TL11, TL21 and TL31 are transparent organic layers each formed of a first organic material, and are high-refractive layers having refractive indices greater than those of the upper electrodes UE1, UE2 and UE3. For example, the refractive index of each of the first transparent layers TL11, TL21 and TL31 is greater than or equal to 1.7 but less than or equal to 2.0.

The second transparent layers TL12, TL22 and TL32 are transparent organic layers each formed of a second organic material, and are low-refractive layers having refractive indices less than those of the first transparent layers TL11, TL21 and TL31. For example, the refractive index of each of the second transparent layers TL12, TL22 and TL32 is greater than or equal to 1.3 but less than or equal to 1.6.

The refractive indices of the sealing layers SE1, SE2 and SE3 which are in contact with the second transparent layers TL12, TL22 and TL32 are greater than those of the second transparent layers TL12, TL22 and TL32. For example, the refractive index of each of the sealing layers SE1, SE2 and SE3 is greater than or equal to 1.7 but less than or equal to 2.0.

As the second organic material for forming the second transparent layers TL12, TL22 and TL32, fluorine resin in which the main chain consists of carbon and which contains fluorine in a substituent is desirable. The second transparent layers TL12, TL22 and TL32 can be formed by a vapor deposition method. The thickness of each of these second transparent layers TL12, TL22 and TL32 is, for example, 20 nm to 500 nm.

The first transparent layers TL11, TL21 and TL31 are spaced apart from each other and are individually formed. Thus, all of the first transparent layers TL11, TL21 and TL31 may be formed of the same material, or one of the first transparent layers TL11, TL21 and TL31 may be formed of a material different from that of the other two transparent layers, or all of the first transparent layers TL11, TL21 and TL31 may be formed of materials different from each other.

The second transparent layers TL12, TL22 and TL32 are spaced apart from each other and are individually formed. Thus, all of the second transparent layers TL12, TL22 and TL32 may be formed of the same material, or one of the second transparent layers TL12, TL22 and TL32 may be formed of a material different from that of the other two transparent layers, or all of the second transparent layers TL12, TL22 and TL32 may be formed of materials different from each other.

All of the thicknesses of the first transparent layers TL11, TL21 and TL31 may be the same as each other, or may be different from each other.

All of the thicknesses of the second transparent layers TL12, TL22 and TL32 may be the same as each other, or may be different from each other.

For example, all of the thicknesses of the second transparent layers TL12, TL22 and TL32 are the same as each other. The thickness of the first transparent layer TL11 in the display element 201 for blue is less than that of the first transparent layer TL31 in the display element 203 for red.

In the display element 201, the thickness of the second transparent layer TL12 is greater than that of the first transparent layer TL11. In the display element 203, the thickness of the first transparent layer TL31 is less than that of the second transparent layer TL32.

Each of the second transparent layers TL12, TL22 and TL32 may be formed of an inorganic material such as lithium fluoride.

All of the layer structures of the cap layers CP1 to CP3 may be the same as each other, or the layer structure of one of the cap layers CP1 to CP3 may be different from the layer structures of the other two cap layers, or all of the layer structures of the cap layers CP1 to CP3 may be different from each other.

Each of the cap layers CP1, CP2 and CP3 may be a stacked layer body consisting of three or more layers.

It should be noted that each of the organic layers OR1, OR2 and OR3 may include, in addition to the functional layers described above, other functional layers such as a carrier generation layer as needed, or at least one of the above functional layers may be omitted.

For example, each of the hole transport layers HTL1, HTL2 and HTL3 is a multilayer body consisting of two thin films formed of materials different from each other as shown by dotted lines in the figure. However, each of the hole transport layers HTL1, HTL2 and HLT3 may be a single-layer body formed of a single material.

In this specification, the configuration of the display elements 201 to 203 shown in FIG. 4 is called a single configuration.

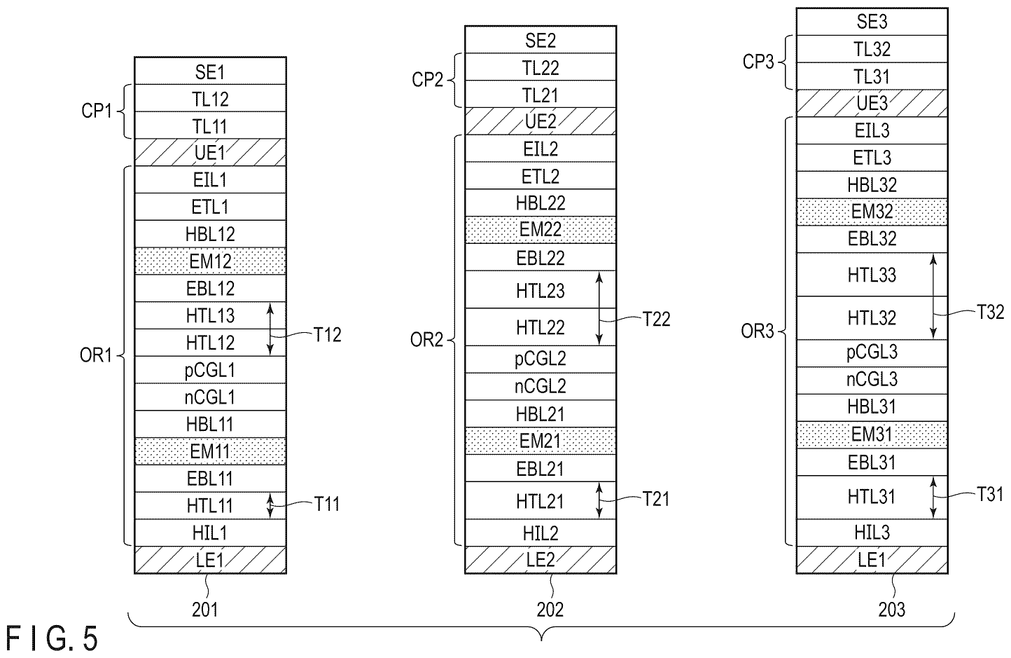

FIG. 5 is a diagram showing another example of the configuration of the display elements 201 to 203.

Here, in the example, this specification explains a case where each lower electrode corresponds to an anode and each upper electrode corresponds to a cathode.

The display element 201 includes the organic layer OR1 between the lower electrode LE1 and the upper electrode UE1.

In the organic layer OR1, the hole injection layer HIL1, a hole transport layer HTL11, an electron blocking layer EBL11, a light emitting layer EM11, a hole blocking layer HBL11, an n-type charge generation layer nCGL1, a p-type charge generation layer pCGL1, a hole transport layer HTL12, a hole transport layer HTL13, an electron blocking layer EBL12, a light emitting layer EM12, a hole blocking layer HBL12, the electron transport layer ETL1 and the electron injection layer EIL1 are stacked in this order.

The hole transport layers HTL11 and HTL12 are formed of, for example, the same material. The hole transport layers HTL12 and HTL13 are formed of, for example, different materials.

The electron blocking layers EBL11 and EBL12 are formed of, for example, the same material. However, they may be formed of different materials.

The light emitting layers EM11 and EM12 are formed of, for example, the same material. However, they may be formed of different materials. Each of the light emitting layers EM11 and EM12 corresponds to the light emitting layer EM1 shown in FIG. 3.

The hole blocking layers HBL11 and HBL12 are formed of, for example, the same material. However, they may be formed of different materials.

The n-type charge generation layer nCGL1 is a functional layer which supplies electrons to the light emitting layer EM11.

The p-type charge generation layer pCGL1 is a functional layer which supplies positive holes to the light emitting layer EM12.

The cap layer CP1 including the first transparent layer TL11 and the second transparent layer TL12 is provided on the upper electrode UE1. The sealing layer SE1 is provided on the second transparent layer TL12.

The display element 202 includes the organic layer OR2 between the lower electrode LE2 and the upper electrode UE2.

In the organic layer OR2, the hole injection layer HIL2, a hole transport layer HTL21, an electron blocking layer EBL21, a light emitting layer EM21, a hole blocking layer HBL21, an n-type charge generation layer nCGL2, a p-type charge generation layer pCGL2, a hole transport layer HTL22, a hole transport layer HTL23, an electron blocking layer EBL22, a light emitting layer EM22, a hole blocking layer HBL22, the electron transport layer ETL2 and the electron injection layer EIL2 are stacked in this order.

The hole transport layers HTL21 and HTL22 are formed of, for example, the same material. The hole transport layers HTL22 and HTL23 are formed of, for example, different materials. For example, thickness T21 of the hole transport layer HTL21 is greater than thickness T11 of the hole transport layer HTL11. Thickness T22 of the hole transport layers HTL22 and HTL23 is greater than thickness T12 of the hole transport layers HTL12 and HTL13.

The electron blocking layers EBL21 and EBL22 are formed of, for example, the same material. However, they may be formed of different materials.

The light emitting layers EM21 and EM22 are formed of, for example, the same material. However, they may be formed of different materials. Each of the light emitting layers EM21 and EM22 corresponds to the light emitting layer EM2 shown in FIG. 3.

The hole blocking layers HBL21 and HBL22 are formed of, for example, the same material. However, they may be formed of different materials.

The n-type charge generation layer nCGL2 is a functional layer which supplies electrons to the light emitting layer EM21.

The p-type charge generation layer pCGL2 is a functional layer which supplies positive holes to the light emitting layer EM22.

The cap layer CP2 including the first transparent layer TL21 and the second transparent layer TL22 is provided on the upper electrode UE2. The sealing layer SE2 is provided on the second transparent layer TL22.

The display element 203 includes the organic layer OR3 between the lower electrode LE3 and the upper electrode UE3.

In the organic layer OR3, the hole injection layer HIL3, a hole transport layer HTL31, an electron blocking layer EBL31, a light emitting layer EM31, a hole blocking layer HBL31, an n-type charge generation layer nCGL3, a p-type charge generation layer pCGL3, a hole transport layer HTL32, a hole transport layer HTL33, an electron blocking layer EBL32, a light emitting layer EM32, a hole blocking layer HBL32, the electron transport layer ETL3 and the electron injection layer EIL3 are stacked in this order.

The hole transport layers HTL31 and HTL32 are formed of, for example, the same material. The hole transport layers HTL32 and HTL33 are formed of, for example, different materials. For example, thickness T31 of the hole transport layer HTL31 is greater than thickness T21 of the hole transport layer HTL21. Thickness T32 of the hole transport layers HTL32 and HTL33 is greater than thickness T22 of the hole transport layers HTL22 and HTL23.

The electron blocking layers EBL31 and EBL32 are formed of, for example, the same material. However, they may be formed of different materials.

The light emitting layers EM31 and EM32 are formed of, for example, the same material. However, they may be formed of different materials. Each of the light emitting layers EM31 and EM32 corresponds to the light emitting layer EM3 shown in FIG. 3.

The hole blocking layers HBL31 and HBL32 are formed of, for example, the same material. However, they may be formed of different materials.

The n-type charge generation layer nCGL3 is a functional layer which supplies electrons to the light emitting layer EM31.

The p-type charge generation layer pCGL3 is a functional layer which supplies positive holes to the light emitting layer EM32.

The cap layer CP3 including the first transparent layer TL31 and the second transparent layer TL32 is provided on the upper electrode UE3. The sealing layer SE3 is provided on the second transparent layer TL32.

In this specification, the configuration of the display elements 201 to 203 shown in FIG. 5 is called a tandem configuration.

Now, this specification explains an example of the manufacturing method of the display device DSP.

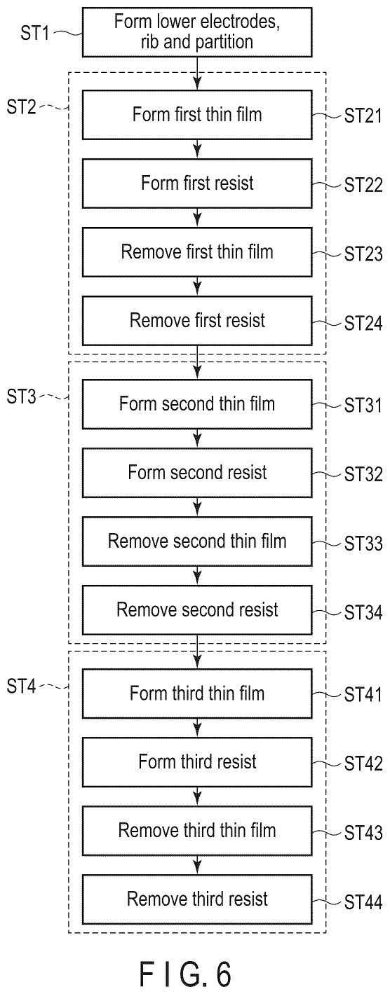

FIG. 6 is a flow diagram for explaining an example of the manufacturing method of the display device DSP.

The manufacturing method shown here roughly includes the process of preparing a processing substrate SUB comprising subpixels SP1, SP2 and SP3 (step ST1), the process of forming the display element 201 of subpixel SP1 (step ST2), the process of forming the display element 202 of subpixel SP2 (step ST3) and the process of forming the display element 203 of subpixel SP3 (step ST4).

In step ST1, first, the processing substrate SUB is prepared by forming the lower electrode LE1 of subpixel SP1, the lower electrode LE2 of subpixel SP2, the lower electrode LE3 of subpixel SP3, the rib 5 and the partition 6 on the substrate 10. As shown in FIG. 3, the circuit layer 11 and the insulating layer 12 are also formed between the substrate 10 and the lower electrodes LE1, LE2 and LE3.

In step ST2, first, a first thin film 31 including the light emitting layer EM1 is formed over subpixel SP1, subpixel SP2 and subpixel SP3 (step ST21). The first thin film 31 is a stacked layer body of the organic layer OR1, upper electrode UE1, cap layer CP1 and sealing layer SE1 shown in FIG. 3. Subsequently, a first resist 41 patterned into a predetermined shape is formed on the first thin film 31 (step ST22). Subsequently, part of the first thin film 31 is removed by etching using the first resist 41 as a mask (step ST23). At this time, for example, the first thin film 31 provided in subpixel SP2 and subpixel SP3 is removed. Subsequently, the first resist 41 is removed (step ST24). In this manner, subpixel SP1 is formed. Subpixel SP1 comprises the display element 201 comprising the first thin film 31 having a predetermined shape.

In step ST3, first, a second thin film 32 including the light emitting layer EM2 is formed over subpixel SP1, subpixel SP2 and subpixel SP3 (step ST31). The second thin film 32 is a stacked layer body of the organic layer OR2, upper electrode UE2, cap layer CP2 and sealing layer SE2 shown in FIG. 3. Subsequently, a second resist 42 patterned into a predetermined shape is formed on the second thin film 32 (step ST32). Subsequently, part of the second thin film 32 is removed by etching using the second resist 42 as a mask (step ST33). At this time, for example, the second thin film 32 provided in subpixel SP1 and subpixel SP3 is removed. Subsequently, the second resist 42 is removed (step ST34). In this manner, subpixel SP2 is formed. Subpixel SP2 comprises the display element 202 comprising the second thin film 32 having a predetermined shape.

In step ST4, first, a third thin film 33 including the light emitting layer EM3 is formed over subpixel SP1, subpixel SP2 and subpixel SP3 (step ST41). The third thin film 33 is a stacked layer body of the organic layer OR3, upper electrode UE3, cap layer CP3 and sealing layer SE3 shown in FIG. 3. Subsequently, a third resist 43 patterned into a predetermined shape is formed on the third thin film 33 (step ST42). Subsequently, part of the third thin film 33 is removed by etching using the third resist 43 as a mask (step ST43). At this time, for example, the third thin film 33 provided in subpixel SP1 and subpixel SP2 is removed. Subsequently, the third resist 43 is removed (step ST44). In this manner, subpixel SP3 is formed. Subpixel SP3 comprises the display element 203 comprising the third thin film 33 having a predetermined shape.

It should be noted that the detailed illustrations of the second thin film 32, the second resist 42, the third thin film 33 and the third resist 43 are omitted.

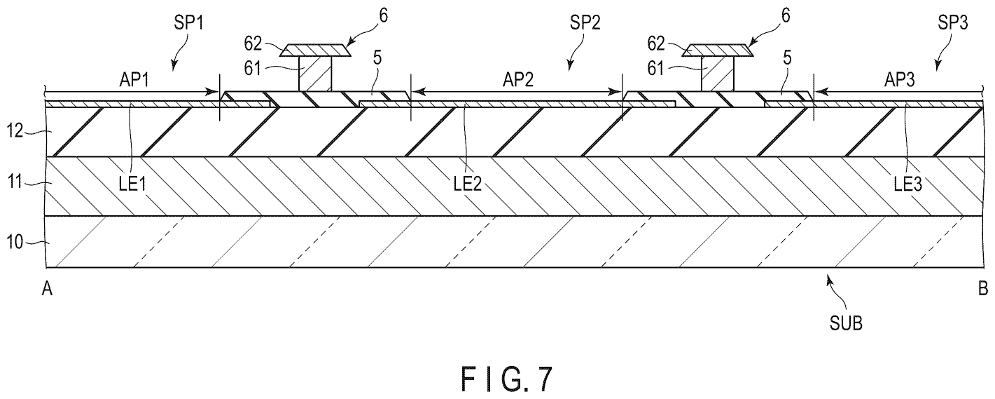

Now, this specification explains step ST1 and step ST2 with reference to FIG. 7 to FIG. 18. The section shown in each of FIG. 7 to FIG. 18 corresponds to, for example, the section taken along the A-B line of FIG. 2.

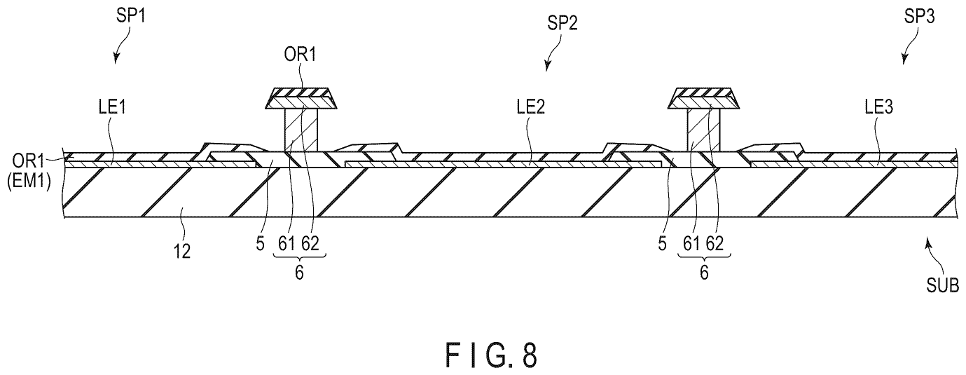

First, in step ST1, as shown in FIG. 7, the processing substrate SUB is prepared. The process of preparing the processing substrate SUB includes the process of forming the circuit layer 11 on the substrate 10, the process of forming the insulating layer 12 on the circuit layer 11, the process of forming the lower electrode LE1 of subpixel SP1, the lower electrode LE2 of subpixel SP2 and the lower electrode LE3 of subpixel SP3 on the insulating layer 12, the process of forming the rib 5 comprising the apertures AP1, AP2 and AP3 overlapping the lower electrodes LE1, LE2 and LE3, respectively, and the process of forming the partition 6 including the lower portion 61 provided on the rib 5 and the upper portion 62 provided on the lower portion 61 and protruding from the side surfaces of the lower portion 61. The rib 5 is formed of, for example, silicon nitride. Of the partition 6, at least the lower portion 61 is formed of a conductive material. In each of FIG. 8 to FIG. 18, the illustrations of the substrate 10 and the circuit layer 11 lower than the insulating layer 12 are omitted.

Subsequently, in step ST21, as shown in FIG. 8 to FIG. 13, the first thin film 31 is formed over subpixel SP1, subpixel SP2 and subpixel SP3.

The process of forming the first thin film 31 is, for example, as follows.

Firstly, as shown in FIG. 8, the organic layer OR1 including the light emitting layer EM1 is formed on the processing substrate SUB.

The organic layer OR1 is formed on each of the lower electrode LE1, the lower electrode LE2 and the lower electrode LE3 and is also formed on each partition 6. Of the organic layer OR1, the portion formed on each upper portion 62 is spaced apart from the portion formed on each of the lower electrodes LE1, LE2 and LE3. The light emitting layer EM1 and various functional layers of the organic layer OR1 are formed by a vapor deposition method.

It should be noted that the organic layer OR1 may comprise the single configuration shown in FIG. 4 or may comprise the tandem configuration shown in FIG. 5.

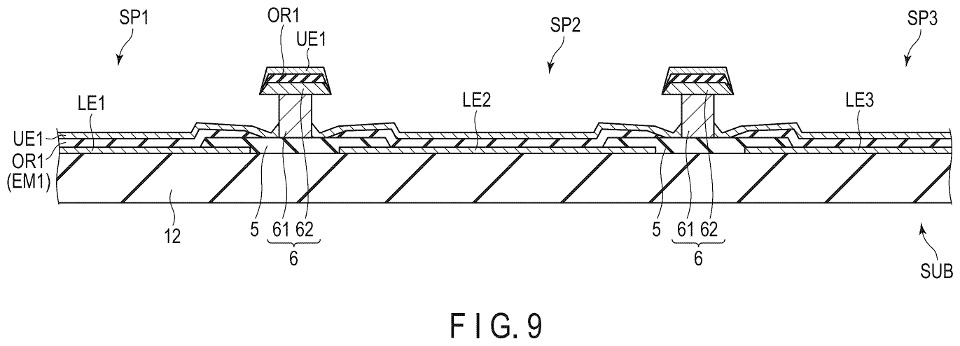

Subsequently, as shown in FIG. 9, the upper electrode UE1 is formed on the organic layer OR1.

The upper electrode UE1 is formed on the organic layer OR1 immediately above each of the lower electrodes LE1, LE2 and LE3, covers the rib 5 and is in contact with the lower portion 61 of each partition 6. The upper electrode UE1 is also formed on the organic layer OR1 immediately above each upper portion 62. Of the upper electrode UE1, the portion which is formed immediately above each upper portion 62 is spaced apart from the portion which is formed immediately above each of the lower electrodes LE1, LE2 and LE3. The upper electrode UE1 is formed of an alloy of magnesium and silver by a vapor deposition method.

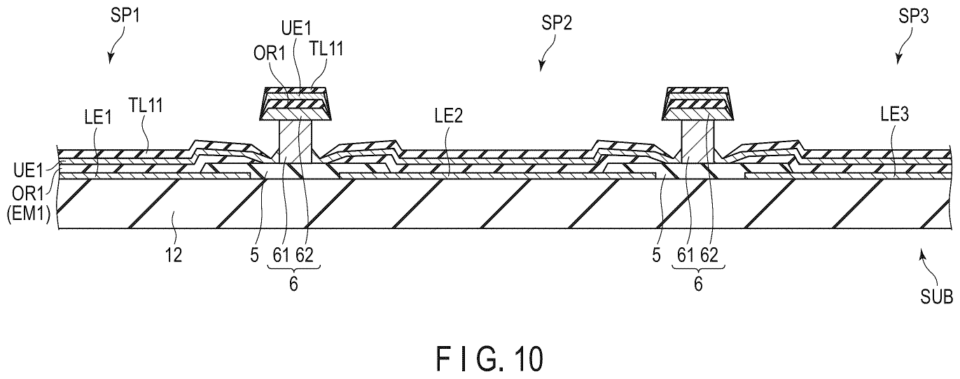

Subsequently, as shown in FIG. 10, the first transparent layer TL11 of the cap layer CP1 is formed on the upper electrode UE1.

The first transparent layer TL11 is formed on the upper electrode UE1 immediately above each of the lower electrodes LE1, LE2 and LE3, and is also formed on the upper electrode UE1 immediately above each upper portion 62. Of the first transparent layer TL11, the portion which is formed immediately above each upper portion 62 is spaced apart from the portion which is formed immediately above each of the lower electrodes LE1, LE2 and LE3. The first transparent layer TL11 is formed of the first organic material by a vapor deposition method.

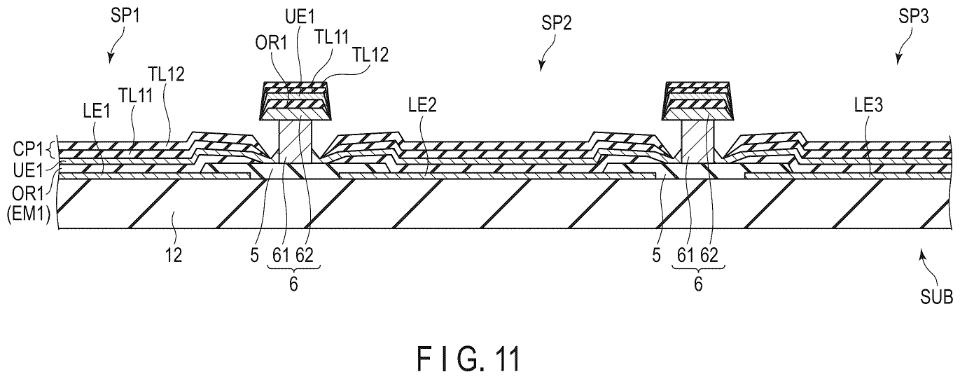

Subsequently, as shown in FIG. 11, the second transparent layer TL12 of the cap layer CP1 is formed on the first transparent layer TL11.

The second transparent layer TL12 is formed on the first transparent layer TL11 immediately above each of the lower electrodes LE1, LE2 and LE3, and is also formed on the first transparent layer TL11 immediately above each upper portion 62. Of the second transparent layer TL12, the portion which is formed immediately above each upper portion 62 is spaced apart from the portion which is formed immediately above each of the lower electrodes LE1, LE2 and LE3. The second transparent layer TL12 is formed of, for example, the second organic material. The second organic material is a material different from the first organic material. The refractive index of the second organic material is lower than that of the first organic material.

The stacked layer body of these first transparent layer TL11 and second transparent layer TL12 forms the cap layer CP1.

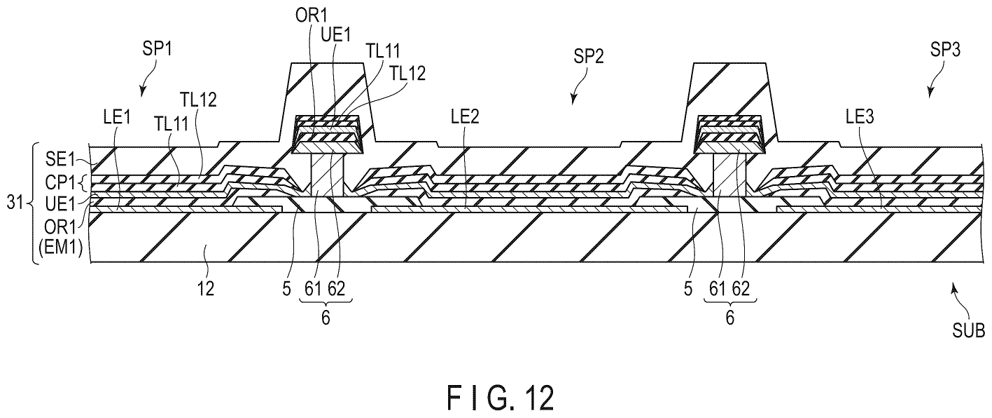

Subsequently, as shown in FIG. 12, the sealing layer SE1 is formed on the second transparent layer TL12. Thus, in the example shown in the figure, the first thin film 31 includes the organic layer OR1, the upper electrode UE1, the cap layer CP1 and the sealing layer SE1.

The sealing layer SE1 is formed so as to cover the second transparent layer TL12 and the partition 6. In other words, the sealing layer SE1 is formed on the second transparent layer TL12 immediately above each of the lower electrodes LE1, LE2 and LE3, and is also formed on the second transparent layer TL12 immediately above each upper portion 62. Moreover, the sealing layer SE1 is in contact with the lower portion 61 of the partition 6. In the sealing layer SE1, the portion which is formed immediately above each upper portion 62 is continuous with the portion which is formed immediately above each of the lower electrodes.

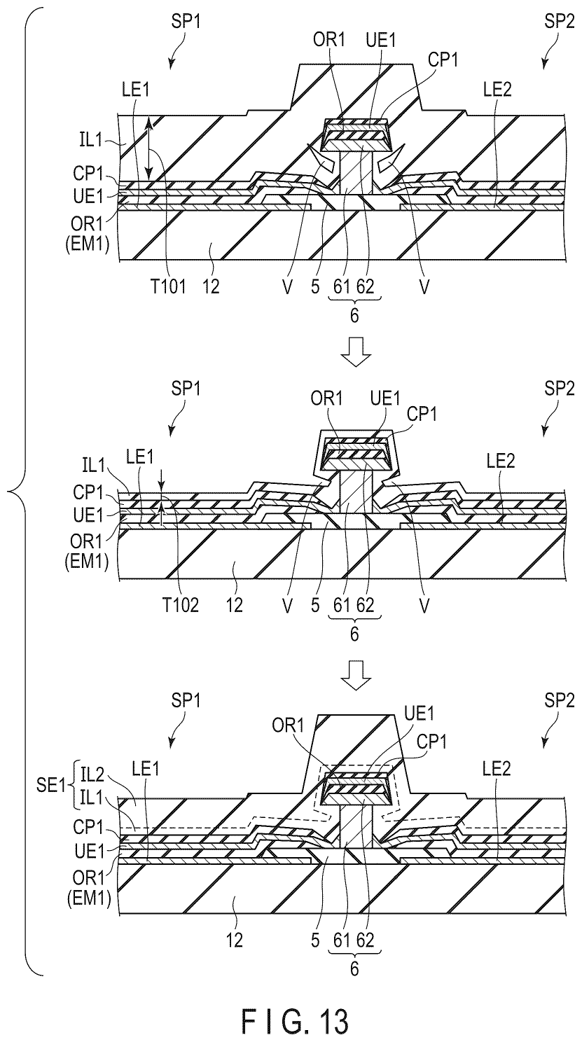

The process of forming the sealing layer SE1 is further explained with reference to FIG. 13. FIG. 13 shows the section of the processing substrate over subpixel SP1 and subpixel SP2.

First, as shown in the upper part of FIG. 13, a first inorganic insulating layer IL1 is formed. The first inorganic insulating layer IL1 is formed of silicon nitride by a chemical vapor deposition (CVD) method.

When this specification focuses attention on the first inorganic insulating layer IL1 located in subpixel SP1, the first inorganic insulating layer IL1 is in contact with the cap layer CP1, is in contact with a side surface of the lower portion 61 of the partition 6 and is in contact with the upper portion 62 of the partition 6. The first inorganic insulating layer IL1 comprises a closed void V under the upper portion 62. Thickness T101 of the first inorganic insulating layer IL1 is, for example, 3 μm immediately above the lower electrode LE1.

Subsequently, as shown in the middle part of FIG. 13, anisotropic dry etching is performed for the entire first inorganic insulating layer IL1 without an intervention of a resist. In anisotropic dry etching, side etching does not easily make progress compared to isotropic dry etching. Therefore, the thickness of the first inorganic insulating layer IL1 located immediately above each of the lower electrodes LE1 and LE2 is reduced, and the thickness of the first inorganic insulating layer IL1 located immediately above the upper portion 62 of the partition 6 is reduced. Further, the first inorganic insulating layer IL1 on the distal end side of each void V is removed, and each void V is opened. After the anisotropic dry etching, immediately above the lower electrode LE1, thickness T102 of the first inorganic insulating layer IL1 is, for example, 0.3 μm.

The first inorganic insulating layer IL1 located under the upper portion 62 of the partition 6 is not substantially removed. In other words, after the anisotropic dry etching, the first inorganic insulating layer IL1 covers the side surfaces of the lower portion 61 of the partition 6 and the bottom surface of the upper portion 62 of the partition 6.

Subsequently, as shown in the lower part of FIG. 13, a second inorganic insulating layer IL2 is formed on the first inorganic insulating layer IL′. The second inorganic insulating layer IL2 is formed of the same material as the first inorganic insulating layer IL′. Thus, the second inorganic insulating layer IL2 is formed of silicon nitride by a CVD method. When the first inorganic insulating layer IL1 and the second inorganic insulating layer IL2 are formed of the same material, the interface between them is not substantially recognized. In other words, although the sealing layer SE1 shown in FIG. 12 is the stacked layer body of the first inorganic insulating layer IL1 and the second inorganic insulating layer IL2, the sealing layer SE1 can be regarded as a single layer. For this reason, undesired reflection of light or scattering inside the sealing layer SE1 is prevented.

In the example shown in the figure, the sealing layer SE1 does not include a void under the upper portion 62. In this manner, as the sealing layer SE1 does not include a void, a crack based on a void can be prevented. It should be noted that the sealing layer SE1 may include a void smaller than each void V shown in the upper part of FIG. 13.

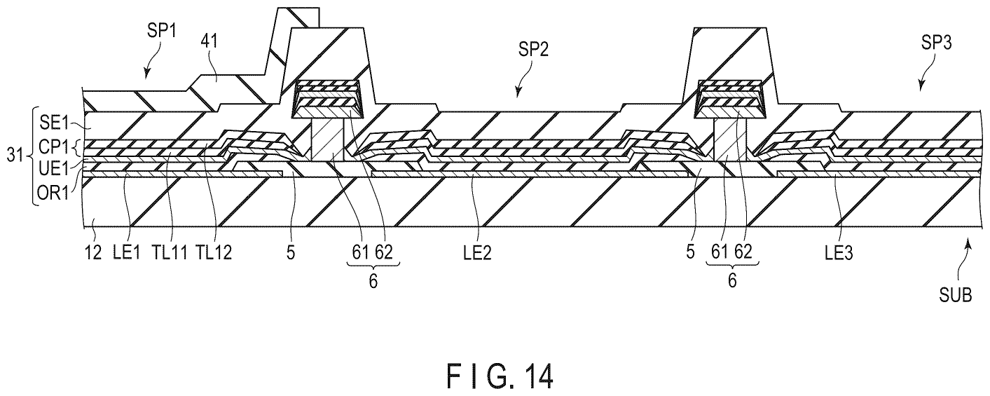

Subsequently, in step ST22, as shown in FIG. 14, the patterned first resist 41 is formed on the sealing layer SE1. The first resist 41 covers the first thin film 31 of subpixel SP1, and the first thin film 31 is exposed from the first resist 41 in subpixels SP2 and SP3. Thus, the first resist 41 overlaps the sealing layer SE1 located immediately above the lower electrode LE1. The first resist 41 extends from subpixel SP1 to the upper side of the partition 6. Immediately above the partition 6 between subpixel SP1 and subpixel SP2, the first resist 41 is provided on the subpixel SP1 side (the left side of the figure), and the sealing layer SE1 is exposed from the first resist 41 on the subpixel SP2 side (the right side of the figure). The sealing layer SE1 is exposed from the first resist 41 in subpixel SP2 and subpixel SP3.

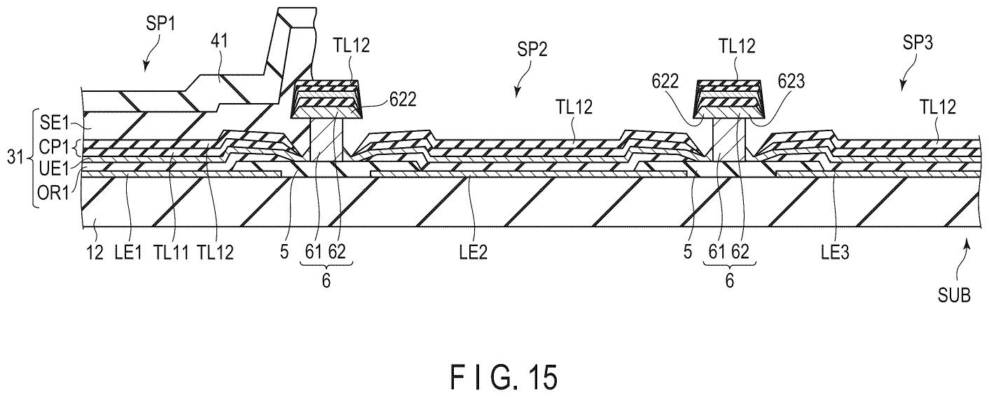

Subsequently, in step ST23, as shown in FIG. 15 to FIG. 17, etching is applied using the first resist 41 as a mask. By this process, the first thin film 31 exposed from the first resist 41 in subpixels SP2 and SP3 is removed, and the first thin film 31 remains in subpixel SP1.

The process of removing the first thin film 31 is, for example, as follows.

First, as shown in FIG. 15, dry etching is performed using the first resist 41 as a mask to remove the sealing layer SE1 exposed from the first resist 41. By this process, of the cap layer CP1, part of the second transparent layer TL12 is exposed from the sealing layer SE1.

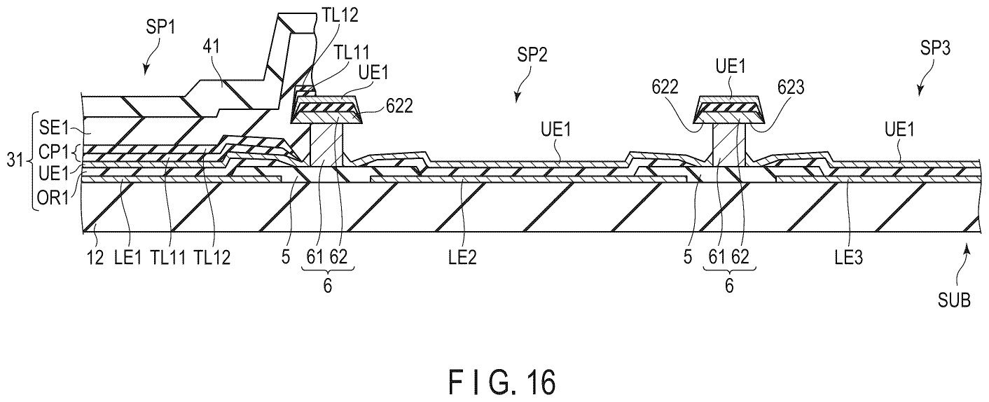

Subsequently, as shown in FIG. 16, ashing (dry etching for emitting oxygen plasma) is performed using the first resist 41 as a mask to remove the second transparent layer TL12 exposed from the sealing layer SE1.

Subsequently, ashing is performed using the first resist 41 as a mask to remove the first transparent layer TL11 exposed from the second transparent layer TL12. By this process, part of the upper electrode UE1 is exposed from the cap layer CP1.

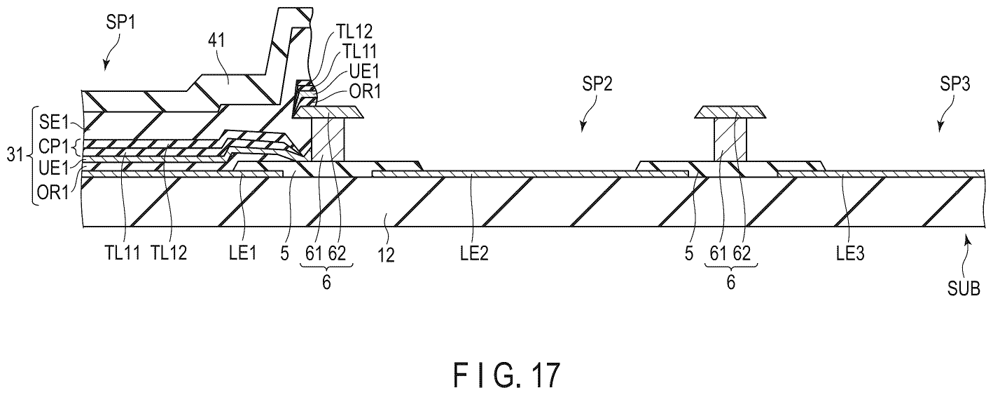

Subsequently, as shown in FIG. 17, wet etching is performed using the first resist 41 as a mask to remove the upper electrode UE1 exposed from the first transparent layer TL11.

Subsequently, asking is performed using the first resist 41 as a mask to remove the organic layer OR1 exposed from the upper electrode UE1.

In this manner, the lower electrode LE2 is exposed in subpixel SP2, and the rib 5 surrounding the lower electrode LE2 is exposed. In subpixel SP3, the lower electrode LE3 is exposed, and the rib 5 surrounding the lower electrode LE3 is exposed. On the partition 6 between subpixel SP1 and subpixel SP2, the subpixel SP2 side is exposed. Further, the partition 6 between subpixel SP2 and subpixel SP3 is exposed.

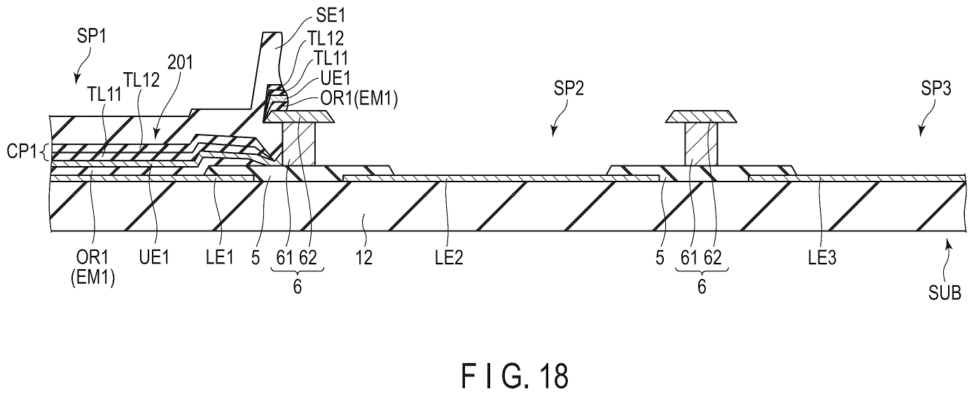

Subsequently, in step ST24, as shown in FIG. 18, the first resist 41 is removed. Thus, the sealing layer SE1 of subpixel SP1 is exposed. Through these steps ST21 to ST24, the display element 201 is formed in subpixel SP1. The display element 201 consists of the lower electrode LE1, the organic layer OR1 including the light emitting layer EM1, the upper electrode UE1, the first transparent layer TL11 and the second transparent layer TL12. The display element 201 is covered with the sealing layer SE1.

A stacked layer body of the organic layer OR1 including the light emitting layer EM1, the upper electrode UE1, the first transparent layer TL11, the second transparent layer TL12 and the sealing layer SE1 is formed on the partition 6 between subpixel SP1 and subpixel SP2. The stacked layer body located on the partition 6 is spaced apart from the organic layer OR1, the upper electrode UE1, the first transparent layer TL11, the second transparent layer TL12 and the sealing layer SE1 constituting the display element 201. Of the partition 6, the portion on the subpixel SP1 side is covered with the sealing layer SE1. It should be noted that the stacked layer body on the partition 6 shown in FIG. 18 is completely eliminated in some cases.

Steps ST31 to ST34 shown in FIG. 6 are similar to steps ST21 to ST24 described above. Through these steps ST31 to ST34, the display element 202 is formed in subpixel SP2 shown in FIG. 3. The display element 202 consists of the lower electrode LE2, the organic layer OR2 including the light emitting layer EM2, the upper electrode UE2, the first transparent layer TL21 and the second transparent layer TL22. The display element 202 is covered with the sealing layer SE2.

Steps ST41 to ST44 shown in FIG. 6 are also similar to steps ST21 to ST24 described above. Through these steps ST41 to ST44, the display element 203 is formed in subpixel SP3 shown in FIG. 3. The display element 203 consists of the lower electrode LE3, the organic layer OR3 including the light emitting layer EM3, the upper electrode UE3, the first transparent layer TL31 and the second transparent layer TL32. The display element 203 is covered with the sealing layer SE3.

In the present embodiment, the display elements 201 to 203 comprise the cap layers CP1 to CP3, respectively, which function as optical adjustment layers. Thus, the light reflected on the light emitting layers EM1 to EM3 is reflected on the interfaces between the first and second transparent layers constituting the cap layers CP1 to CP3, respectively, and is reflected on the upper electrodes again. By the microcavity effect using such interference of reflected light, the light extraction efficiency for each display element can be improved.

Now, the manufacturing device of the display device DSP is explained. Here, for example, this specification explains a manufacturing device 100 for forming the display element 201 comprising the tandem configuration shown in FIG. 5. It should be noted that the manufacturing device for forming each of the display elements 202 and 203 comprising a tandem configuration can be configured in a manner similar to that of the manufacturing device 100 explained here.

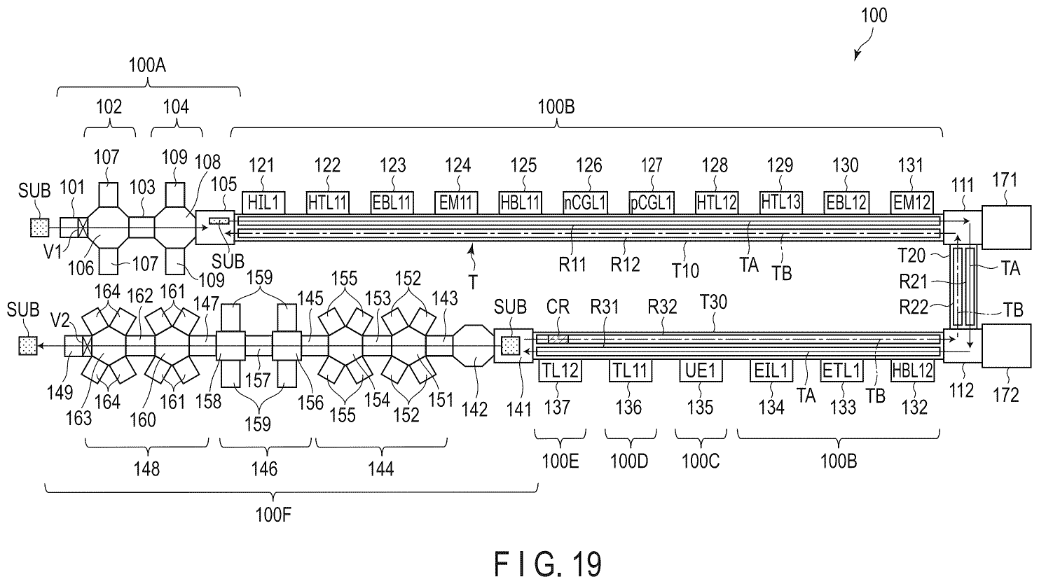

FIG. 19 is a diagram for explaining a configuration example of the manufacturing device 100.

The manufacturing device 100 is applied in the process of forming the first thin film 31 (step ST21) explained with reference to FIG. 6. No mask is provided in the processing substrate SUB which is carried in the manufacturing device 100. In addition, no mask is provided in the processing substrate SUB inside the manufacturing device 100.

The manufacturing device 100 comprises a preprocessing portion 100A, a first evaporation portion 100B, a second evaporation portion 100C, a third evaporation portion 100D, a fourth evaporation portion 100E, a post-processing portion 100F and a conveyance mechanism T. The preprocessing portion 100A is connected to the upstream side in the first direction TA (shown by the solid lines in the figure) of the conveyance mechanism T. The post-processing portion 100F is connected to the downstream side in the first direction TA of the conveyance mechanism T.

The preprocessing portion 100A is configured to perform predetermined preprocessing for the processing substrate SUB. The preprocessing portion 100A comprises a first load lock chamber 101, a baking portion 102, a transfer chamber 103, a plasma processing portion 104 and a securing portion 105.

The first load lock chamber 101 comprises a vacuum pump which decompresses the inside of the chamber after the processing substrate SUB comprising the lower electrodes, the rib, the partition, etc., as explained in step ST1 is horizontally carried in the chamber.

The baking portion 102 comprises a handling chamber 106 connected to the first load lock chamber 101 and the transfer chamber 103, and a plurality of baking chambers 107 connected to the handling chamber 106.

The handling chamber 106 is connected to the first load lock chamber 101 via a gate valve V1. A conveyance robot which extracts the processing substrate SUB having been carried in the first load lock chamber 101, conveys the processing substrate SUB to each baking chamber 107, extracts the processing substrate SUB having been conveyed to the baking chamber 107 and conveys the processing substrate SUB to the transfer chamber 103 is provided. Each baking chamber 107 comprises a heating mechanism for heating up the washed processing substrate SUB at a low temperature to remove moisture from the processing substrate SUB.

The plasma processing portion 104 comprises a handling chamber 108 connected to the transfer chamber 103 and the securing portion 105, and a plurality of plasma chambers 109 connected to the handling chamber 108.

The handling chamber 108 comprises a conveyance robot which extracts the processing substrate SUB having been conveyed to the transfer chamber 103, conveys the processing substrate SUB to each plasma chamber 109, extracts the processing substrate SUB having been conveyed to the plasma chamber 109 and conveys the processing substrate SUB to the securing portion 105. Each plasma chamber 109 comprises a plasma source which irradiates the processing substrate SUB with plasma to reform the surfaces of the lower electrodes LE1, LE2 and LE3.

The securing portion 105 comprises a mechanism for securing the processing substrate SUB having been conveyed by the handling chamber 108 to a dedicated carrier CR by an electrostatic chuck. In the example shown in the figure, the securing portion 105 comprises a vertical raising mechanism for rotating the processing substrate SUB having been conveyed horizontally by 90° to raise the processing substrate SUB perpendicularly. The securing portion 105 conveys the carrier CR to which the processing substrate SUB is secured to the conveyance mechanism T.

The conveyance mechanism T comprises a first conveyance portion T10, a second conveyance portion T20, a third conveyance portion T30 and direction conversion portions 111 and 112. The first conveyance portion T10 is connected to the securing portion 105 and the direction conversion portion 111. The second conveyance portion T20 is connected to the direction conversion portions 111 and 112. The third conveyance portion T30 is connected to the direction conversion portion 112 and the detachment portion 141 of the post-processing portion 100F.

The first conveyance portion T10 comprises a first rail R11 and a second rail R12.

The second conveyance portion T20 comprises a first rail R21 and a second rail R22.

The third conveyance portion T30 comprises a first rail R31 and a second rail R32.

The first rails R11, R21 and R31 are provided to convey the carrier CR to which the processing substrate SUB is secured in the first direction TA shown by solid lines in the figure.

The second rails R12, R22 and R32 are provided to convey the carrier CR which has been detached from the processing substrate SUB in the second direction TB shown by alternate long and short dash lines in the figure. The second direction TB is the opposite direction of the first direction TA.

In the example shown in the figure, the direction conversion portions 111 and 112 are configured to convert the conveyance direction of the carrier CR by 90°.

The conveyance mechanism T is configured to receive the processing substrate SUB and carrier CR having been conveyed from the preprocessing portion 100A, convey them in the first direction TA and convey them to the post-processing portion 100F. The conveyance mechanism T is configured to receive the carrier CR having been conveyed from the post-processing portion 100F, convey the carrier CR in the second direction TB and convey the carrier CR to the preprocessing portion 100A.

The conveyance mechanism T comprises a storage portion 171 connected to the direction conversion portion 111 and a storage portion 172 connected to the direction conversion portion 112. For example, the storage portions 171 and 172 are provided to temporarily store the carrier CR at the time of the maintenance of the manufacturing device 100.

The first evaporation portion 100B, the second evaporation portion 100C, the third evaporation portion 100D and the fourth evaporation portion 100E are arranged in order in the first direction TA of the conveyance mechanism T. Thus, the first evaporation portion 100B is located in the upstream side in the first direction TA, and the fourth evaporation portion 100E is located in the downstream side in the first direction TA.

As explained with reference to FIG. 8, the first evaporation portion 100B comprises a plurality of evaporation chambers 121 to 134 for forming the organic layer OR1 on the lower electrodes LE1, LE2 and LE3 in the processing substrate SUB.

The evaporation chambers 121 to 131 are arranged in order in the first direction TA of the first conveyance portion T10.

The evaporation chambers 132 to 134 are arranged in order in the first direction TA of the third conveyance portion T30.

The evaporation chamber 121 is configured to form the hole injection layer HIL1 on the lower electrodes LE1, LE2 and LE3.

The evaporation chamber 122 is configured to form the hole transport layer HTL11 on the hole injection layer HIL1.

The evaporation chamber 123 is configured to form the electron blocking layer EBL11 on the hole transport layer HTL11.

The evaporation chamber 124 is configured to form the light emitting layer EM11 on the electron blocking layer EBL11.

The evaporation chamber 125 is configured to form the hole blocking layer HBL11 on the light emitting layer EM11.

The evaporation chamber 126 is configured to form the n-type charge generation layer nCGL1 on the hole blocking layer HBL11.

The evaporation chamber 127 is configured to form the p-type charge generation layer pCGL1 on the n-type charge generation layer nCGL1.

The evaporation chamber 128 is configured to form the hole transport layer HTL12 on the p-type charge generation layer pCGL1.

The evaporation chamber 129 is configured to form the hole transport layer HTL13 on the hole transport layer HTL12.

The evaporation chamber 130 is configured to form the electron blocking layer EBL12 on the hole transport layer HTL13.

The evaporation chamber 131 is configured to form the light emitting layer EM12 on the electron blocking layer EBL12.

The evaporation chamber 132 is configured to form the hole blocking layer HBL12 on the light emitting layer EM12.

The evaporation chamber 133 is configured to form the electron transport layer ETL1 on the hole blocking layer HBL12.

The evaporation portion 134 is configured to form the electron injection layer EIL1 on the electron transport layer ETL1.

The second evaporation portion 100C comprises an evaporation chamber 135 for forming the upper electrode UE1 on the organic layer OR1 (electron injection layer EIL1) as explained with reference to FIG. 9. The evaporation chamber 135 is located on the downstream side of the evaporation chamber 134 in the first direction TA.

The third evaporation portion 100D comprises an evaporation chamber 136 for forming the first transparent layer TL11 on the upper electrode UE1 as explained with reference to FIG. 10.

The fourth evaporation portion 100E comprises an evaporation chamber 137 for forming the second transparent layer TL12 on the first transparent layer TL11 as explained with reference to FIG. 11.

The evaporation chambers 135 to 137 are arranged in order in the first direction TA of the third conveyance portion T30.

The post-processing portion 100F is configured to perform predetermined post-processing for the processing substrate SUB. The post-processing portion 100F comprises the detachment portion 141, a handling chamber 142, a transfer chamber 143, a first deposition portion 144, a transfer chamber 145, an etching portion 146, a transfer chamber 147, a second deposition portion 148 and a second load lock chamber 149.

The detachment portion 141 is connected to the third conveyance portion T30 of the conveyance mechanism T. The detachment portion 141 comprises a mechanism for receiving the processing substrate SUB and carrier CR having been conveyed through the first rail R31 of the third conveyance portion T30, releasing the securing applied by the electrostatic chuck and detaching the processing substrate SUB from the carrier CR. In the example shown in the figure, the detachment portion 141 comprises a mechanism for rotating the processing substrate SUB having been conveyed perpendicularly by 90° to lay down the processing substrate SUB horizontally.

The handling chamber 142 is connected to the detachment portion 141 and the transfer chamber 143. The handling chamber 142 comprises a conveyance robot which conveys the processing substrate SUB which has been conveyed to the detachment portion 141 to the transfer chamber 143.

The first deposition portion 144 comprises a handling chamber 151 connected to the transfer chamber 143 and a transfer chamber 153, a plurality of CVD chambers 152 connected to the handling chamber 151, a handling chamber 154 connected to the transfer chamber 153 and the transfer chamber 145, and a plurality of CVD chambers 155 connected to the handling chamber 154.

The handling chamber 151 comprises a conveyance robot which extracts the processing substrate SUB from the transfer chamber 143, conveys the processing substrate SUB to one of the CVD chambers 152, extracts the processing substrate SUB from the CVD chamber 152 and conveys the processing substrate SUB to the transfer chamber 153.

The handling chamber 154 comprises a conveyance robot which extracts the processing substrate SUB from the transfer chamber 153, conveys the processing substrate SUB to one of the CVD chambers 155, extracts the processing substrate SUB from the CVD chamber 155 and conveys the processing substrate SUB to the transfer chamber 145.

The CVD chambers 152 and 155 are configured to form the first inorganic insulating layer IL1 which could be the sealing layer SE1 as shown in the upper part of FIG. 13. Regarding the processing substrate SUB in which the first inorganic insulating layer IL1 is formed in the CVD chambers 152, the handling chamber 154 conveys the processing substrate SUB to the transfer chamber 145 without conveyance to the CVD chambers 155.

The etching portion 146 comprises a handing chamber 156 connected to the transfer chamber 145 and a transfer chamber 157, a handling chamber 158 connected to the transfer chamber 157 and the transfer chamber 147, and a plurality of etching chambers 159 connected to the handling chambers 156 and 158.

The handling chamber 156 comprises a conveyance robot which extracts the processing substrate SUB from the transfer chamber 145, conveys the processing substrate SUB to one of the etching chambers 159, extracts the processing substrate SUB from the etching chamber 159 and conveys the processing substrate SUB to the transfer chamber 157.

The handling chamber 158 comprises a conveyance robot which extracts the processing substrate SUB from the transfer chamber 157, conveys the processing substrate SUB to one of the etching chambers 159, extracts the processing substrate SUB from the etching chamber 159 and conveys the processing substrate SUB to the transfer chamber 147.

The etching chambers 159 are configured to perform the anisotropic dry etching of the first inorganic insulating layer IL1 as shown in the middle part of FIG. 13. Regarding the processing substrate SUB to which the dry etching is applied in the etching chamber 159 in the preceding stage, the handling chamber 158 conveys the processing substrate SUB to the transfer chamber 147 without conveyance to the etching chamber 159 in the subsequent stage.

The second deposition portion 148 comprises a handling chamber 160 connected to the transfer chamber 147 and a transfer chamber 162, a plurality of CVD chambers 161 connected to the handling chamber 160, a handling chamber 163 connected to the transfer chamber 162 and the second load lock chamber 149, and a plurality of CVD chambers 164 connected to the handling chamber 163.

The handling chamber 160 comprises a conveyance robot which extracts the processing substrate SUB from the transfer chamber 147, conveys the processing substrate SUB to one of the CVD chambers 161, extracts the processing substrate SUB from the CVD chamber 161 and conveys the processing substrate SUB to the transfer chamber 162.

The handling chamber 163 comprises a conveyance robot which extracts the processing substrate SUB from the transfer chamber 162, conveys the processing substrate SUB to one of the CVD chambers 164, extracts the processing substrate SUB from the CVD chamber 164 and conveys the processing substrate SUB to the second load lock chamber 149.

The CVD chambers 161 and 164 are configured to form the second inorganic insulating layer IL2 which could be the sealing layer SE1 as shown in the lower part of FIG. 13. Regarding the processing substrate SUB in which the second inorganic insulating layer IL2 is formed in the CVD chambers 161, the handling chamber 163 conveys the processing substrate SUB to the second load lock chamber 149 without conveyance to the CVD chambers 164.

The second load lock chamber 149 is connected to the handling chamber 163 via a gate valve V2. The second load lock chamber 149 comprises a vacuum pump which decompresses the inside of the chamber after the processing substrate SUB is horizontally carried out of the chamber.

The conveyance path of the processing substrate SUB from the first load lock chamber 101 to the second load lock chamber 149 or the conveyance path between the gate valve V1 and the gate valve V2 is maintained as a vacuum. Here, the vacuum state corresponds to a decompression state lower than atmospheric pressure.

Now, the flow of the processing substrate SUB in the manufacturing device 100 is explained.

In a state where the gate valve V1 is closed, the processing substrate SUB is carried in the first load lock chamber 101. Subsequently, the pressure of the inside of the first load lock chamber 101 is decreased to a pressure which is equal to that of the baking portion 102. Subsequently, the gate valve V1 opens, and the processing substrate SUB is conveyed from the first load lock chamber 101 to the baking portion 102. The processing substrate SUB is conveyed to the plasma processing portion 104 after being baked in the baking portion 102. The processing substrate SUB is conveyed to the securing portion 105 after a plasma process is applied in the plasma processing portion 104.

In the securing portion 105, the substrate SUB which has been conveyed horizontally is secured to the carrier CR and is converted to a perpendicular conveyance posture. The processing substrate SUB secured to the carrier CR is conveyed in the first direction TA in the first rail R11 of the first conveyance portion T10. While the processing substrate SUB is conveyed in the first conveyance portion T10, the materials for forming the layers of the organic layer OR1 are deposited in series on the processing substrate SUB in the evaporation chambers 121 to 131 of the first evaporation portion 100B.

Subsequently, the processing substrate SUB is transferred to the first rail R21 of the second conveyance portion T20 in the direction conversion portion 111 and is conveyed in the first direction TA in the first rail R21. Further, the processing substrate SUB is transferred to the first rail R31 of the third conveyance portion T30 in the direction conversion portion 112 and is conveyed in the first direction TA in the first rail R31.

While the processing substrate SUB is conveyed in the third conveyance portion T30, the materials for forming the layers of the organic layer OR1 are deposited in series on the processing substrate SUB in the evaporation chambers 132 to 134 of the first evaporation portion 100B. Subsequently, the material for forming the upper electrode UE1 is deposited on the processing substrate SUB in the evaporation chamber 135 of the second evaporation portion 100C.

Subsequently, the material for forming the first transparent layer TL11 is deposited on the processing substrate SUB in the evaporation chamber 136 of the third evaporation portion 100D. Subsequently, the material for forming the second transparent layer TL12 is deposited on the processing substrate SUB in the evaporation chamber 137 of the fourth evaporation portion 100E.

Subsequently, the processing substrate SUB is conveyed to the detachment portion 141. In the detachment portion 141, the processing substrate SUB is detached from the carrier CR and is converted to a horizontal conveyance posture. Subsequently, the processing substrate SUB is conveyed to the first deposition portion 144.

The carrier CR which has been detached from the processing substrate SUB in the detachment portion 141 is conveyed in the second direction TB in the second rail R32 of the third conveyance portion T30, is transferred to the second rail R22 of the second conveyance portion T20 in the direction conversion portion 112, is conveyed in the second direction TB in the second rail R22, is transferred to the second rail R12 of the first conveyance portion T10 in the direction conversion portion 111, is conveyed in the second direction TB in the second rail R12 and is conveyed to the securing portion 105.

The processing substrate SUB which has been conveyed to the first deposition portion 144 is conveyed to one of the CVD chambers 152 and 155. In the CVD chambers 152 and 155, the material for forming the first inorganic insulating layer IL1 is deposited on the processing substrate SUB. Subsequently, the processing substrate SUB is conveyed to the etching portion 146.

The processing substrate SUB which has been conveyed to the etching portion 146 is conveyed to one of the etching chambers 159. In the etching chambers 159, anisotropic dry etching is performed such that the thickness of the first inorganic insulating layer IL1 is reduced. Subsequently, the processing substrate SUB is conveyed to the second deposition portion 148.

The processing substrate SUB which has been conveyed to the second deposition portion 148 is conveyed to one of the CVD chambers 161 and 164. In the CVD chambers 161 and 164, the material for forming the second inorganic insulating layer IL2 is deposited on the processing substrate SUB. Subsequently, the processing substrate SUB is conveyed to the second load lock chamber 149.

Subsequently, the gate valve V2 is closed. After the inside of the second load lock chamber 149 is restored to atmospheric pressure, the processing substrate SUB is carried out of the manufacturing device 100 through the second load lock chamber 149.

In the manufacturing device 100 shown in FIG. 19, the case where the display element 201 comprising a tandem configuration is formed is explained. In the manufacturing device 100 shown in the figure, the display element 201 comprising a single configuration can be also formed. Specifically, the display element 201 shown in FIG. 4 can be formed by stopping the evaporation of the materials for the processing substrate SUB in the evaporation chambers 126 to 132 of the first evaporation portion 100B.

In the manufacturing device 100 comprising this configuration, the first load lock chamber 101 for carrying the processing substrate SUB into the device and the second load lock chamber 149 for carrying the processing substrate SUB out of the device are independently provided. In addition, the conveyance path of the processing substrate SUB from the first load lock chamber 101 to the second load lock chamber 149 is limited to one direction. Thus, complicated conveyance control is unnecessary. Further, a space for causing the processing substrate SUB to wait is unneeded. In addition, the retention of the processing substrate SUB on the conveyance path is prevented. Moreover, the conveyance path which should be maintained as a vacuum is shortened. Thus, the reduction in the production efficiency can be prevented.

In addition, the manufacturing device 100 comprising such a configuration can easily form both a display element comprising a single configuration and a display element comprising a tandem configuration.

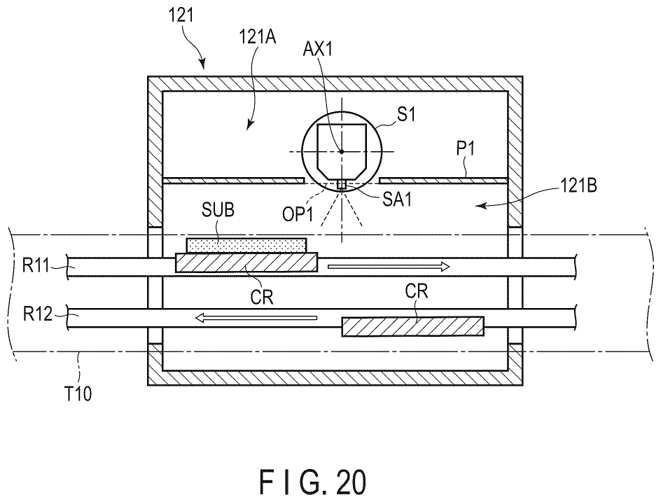

FIG. 20 is a cross-sectional view showing a configuration example of the typical evaporation chamber 121.

The evaporation chamber 121 comprises a partition plate P1. The partition plate P1 partitions the evaporation chamber 121 into a first space 121A and a second space 121B. An evaporation source S1 is accommodated in the first space 121A. The second space 121B is a space to which the processing substrate SUB is conveyed with the carrier CR. In the second space 121B, the first rail R11 and the second rail R12 are provided. The evaporation source S1 is configured to emit the material for forming the hole injection layer HIL1.

The other evaporation chambers 122 to 137 shown in FIG. 19 are configured in the same manner as the evaporation chamber 121 shown in FIG. 20.

The evaporation source accommodated in each evaporation chamber is configured to heat a material, evaporate the material and continuously emit the material while the manufacturing device 100 operates. In a mode in which the emitted material is not deposited on the processing substrate SUB, the evaporation source is set such that the discharge port faces the first space. In a mode in which the emitted material is deposited on the processing substrate SUB, the evaporation source is set such that the discharge port faces the second space.

For example, in the evaporation chamber 121, the evaporation source S1 is configured to rotate around a rotation axis AX1. The evaporation source S1 extends along the rotation axis AX1. The partition plate P1 comprises an opening OP1 shown by the dotted line. The opening OP1 faces the evaporation source S1.

In the example shown in the figure, the evaporation source S1 is set so as to be in a mode in which the emitted material is deposited on the processing substrate SUB, and a discharge port SA1 faces the second space 121B. By this configuration, the material emitted from the evaporation source S1 is deposited on the processing substrate SUB which has been conveyed with the carrier CR.

To the contrary, in a mode in which the emitted material is not deposited on the processing substrate SUB, the evaporation source S1 rotates around the rotation axis AX1 such that the discharge port SA1 faces the first space 121A. By this configuration, the material emitted from the evaporation source S1 is not deposited on the processing substrate SUB which has been conveyed with the carrier CR.

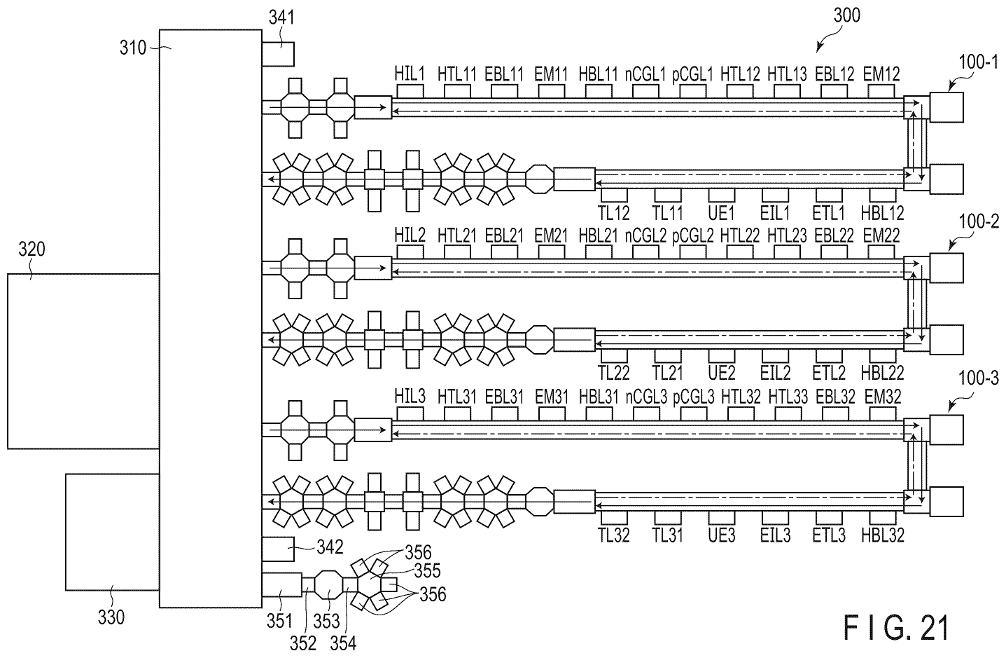

FIG. 21 is a diagram showing a configuration example of a manufacturing system 300 comprising the manufacturing device 100 shown in FIG. 19.

The manufacturing system 300 comprises a substrate cassette compartment 310, a processing portion 320, an examination portion 330 and a plurality of manufacturing devices 100-1 to 100-3.

The substrate cassette compartment 310 accommodates a plurality of substrate cassettes. Each substrate cassette holds a plurality of processing substrates SUB. The substrate cassette compartment 310 conveys the processing substrates SUB to the processing portion 320, the examination portion 330, the manufacturing devices 100-1 to 100-3, etc. Further, the processing substrates SUB in which the process in each portion is completed are carried into the substrate cassette compartment 310.

The processing portion 320 comprises a photolithography module, an evaporation device, a CVD device, an etching device, etc.

The processing portion 320 performs step ST1 shown in FIG. 6 and forms a processing substrate SUB comprising lower electrodes, a rib and a partition.

The processing portion 320 forms the first resist in step ST22, forms the second resist in step ST32 and forms the third resist in step ST42.

The processing portion 320 performs etching using the first resist as a mask in step ST23, performs etching using the second resist as a mask in step ST33 and performs etching using the third resist as a mask in step ST43.

The processing portion 320 removes the first resist in step ST24, removes the second resist in step ST34 and removes the third resist in step ST44.

The examination portion 330 comprises various examination devices.

The examination portion 330 examines whether or not the shape of the partition (especially, the widths of the protrusions 621 to 623) is within a predetermined range.

The examination portion 330 examines whether or not a foreign substance is present on the surface of the processing substrate SUB.

The examination portion 330 examines whether or not each organic layer, each upper electrode, each cap layer and each sealing layer are formed into desired shapes.

The manufacturing device 100-1 is the same as the manufacturing device 100 shown in FIG. 19. The manufacturing devices 100-2 to 100-3 are configured in a manner similar to that of the manufacturing device 100. In the figure, the name of the layer formed in the conveyed processing substrate SUB is added to each evaporation chamber.

In this manufacturing system 300, first, a processing substrate SUB comprising a partition, etc., is formed in the processing portion 320. Subsequently, the processing substrate SUB is conveyed to the substrate cassette compartment 310.

The processing substrate SUB which has been carried out of the substrate cassette compartment 310 is washed in a washing portion 341. The washed processing substrate SUB is conveyed to the manufacturing device 100-1. The manufacturing device 100-1 performs step ST21 for the processing substrate SUB. By this process, the first thin film is formed in the processing substrate SUB.

The processing substrate which has been carried out of the manufacturing device 100-1 is conveyed to the processing portion 320. The processing portion 320 performs steps ST22 to ST24 for the processing substrate SUB.

Subsequently, the processing substrate SUB is conveyed to the manufacturing device 100-2. The processing substrate SUB should be preferably washed in the washing portion 341 before it is conveyed to the manufacturing device 100-2. The manufacturing device 100-2 performs step ST31 for the processing substrate SUB. By this process, the second thin film is formed in the processing substrate SUB.

The processing substrate which has been carried out of the manufacturing device 100-2 is conveyed to the processing portion 320. The processing portion 320 performs steps ST32 to ST34 for the processing substrate SUB.

Subsequently, the processing substrate SUB is conveyed to the manufacturing device 100-3. The processing substrate SUB should be preferably washed in the washing portion 341 before it is conveyed to the manufacturing device 100-3. The manufacturing device 100-3 performs step ST41 for the processing substrate SUB. By this process, the third thin film is formed in the processing substrate SUB.

The processing substrate which has been carried out of the manufacturing device 100-3 is conveyed to the processing portion 320. The processing portion 320 performs steps ST42 to ST44 for the processing substrate SUB. Subsequently, the processing substrate SUB is conveyed to the substrate cassette compartment 310.

Subsequently, the processing substrate SUB which has been carried out of the substrate cassette compartment 310 is washed in a washing portion 342. The washed processing substrate SUB is conveyed to an ink-jet device 351. The ink-jet device 351 applies an organic insulating material to the processing substrate SUB. By this process, the protective layer 13 shown in FIG. 3 is formed.

The processing substrate SUB in which the protective layer 13 is formed is conveyed to a transfer chamber 352 and is conveyed to a transfer chamber 354 via a handling chamber 353. A handling chamber 355 conveys the processing substrate SUB having been conveyed to the transfer chamber 354 to one of CVD chambers 356. The CVD chamber 356 forms the sealing layer 14 shown in FIG. 3. In this manner, the display device DSP comprising the cross-sectional structure shown in FIG. 3 is manufactured.

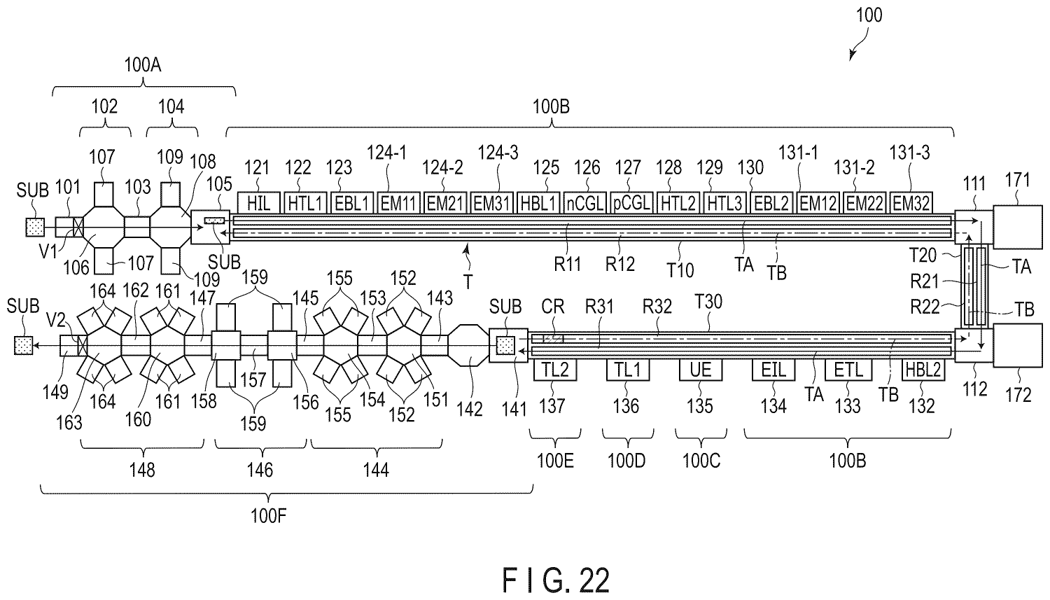

FIG. 22 is a diagram for explaining another configuration example of the manufacturing device 100.

The configuration example shown in FIG. 22 is different from the configuration example shown in FIG. 19 in respect that the first evaporation portion 100B includes evaporation chambers for forming the light emitting layers EM2 and EM3.

Evaporation chambers 124-1 to 124-3 are located between the evaporation chamber 123 and the evaporation chamber 125. The evaporation chambers 124-1 to 124-3 are arranged in order in the first direction TA of the first conveyance portion T10.

Evaporation chambers 131-1 to 131-3 are located between the evaporation chamber 130 and the direction conversion portion 111. The evaporation chambers 131-1 to 131-3 are arranged in order in the first direction TA of the first conveyance portion T10.

The evaporation chamber 121 is configured to form, as a hole injection layer HIL, the hole injection layers HIL1 to HIL3 of the display elements 201 to 203.

The evaporation chamber 122 is configured to form, as a hole transport layer HTL1, the hole transport layers HTL11 to HTL31 of the display elements 201 to 203.

The evaporation chamber 123 is configured to form, as an electron blocking layer EBL1, the electron blocking layers EBL11 to EBL31 of the display elements 201 to 203.

The evaporation chamber 124-1 is configured to form the light emitting layer EM11 of the display element 201.

The evaporation chamber 124-2 is configured to form the light emitting layer EM21 of the display element 202.

The evaporation chamber 124-3 is configured to form the light emitting layer EM31 of the display element 203.

The evaporation chamber 125 is configured to form, as a hole blocking layer HBL1, the hole blocking layers HBL11 to HBL31 of the display elements 201 to 203.

The evaporation chamber 126 is configured to form, as an n-type charge generation layer nCGL, the n-type charge generation layers nCGL1 to nCGL3 of the display elements 201 to 203.

The evaporation chamber 127 is configured to form, as a p-type charge generation layer pCGL, the p-type charge generation layers pCGL1 to pCGL3 of the display elements 201 to 203.

The evaporation chamber 128 is configured to form, as a hole transport layer HTL2, the hole transport layers HTL12 to HTL32 of the display elements 201 to 203.

The evaporation chamber 129 is configured to form, as a hole transport layer HTL3, the hole transport layers HTL13 to HTL33 of the display elements 201 to 203.

The evaporation chamber 130 is configured to form, as an electron blocking layer EBL2, the electron blocking layers EBL12 to EBL32 of the display elements 201 to 203.

The evaporation chamber 131-1 is configured to form the light emitting layer EM12 of the display element 201.

The evaporation chamber 131-2 is configured to form the light emitting layer EM22 of the display element 202.

The evaporation chamber 131-3 is configured to form the light emitting layer EM32 of the display element 203.

The evaporation chamber 132 is configured to form, as a hole blocking layer HBL2, the hole blocking layers HBL12 to HBL32 of the display elements 201 to 203.

The evaporation chamber 133 is configured to form, as an electron transport layer ETL, the electron transport layers ETL1 to ETL3 of the display elements 201 to 203.

The evaporation chamber 134 is configured to form, as an electron injection layer EIL, the electron injection layers EIL1 to EIL3 of the display elements 201 to 203.

The evaporation chamber 135 is configured to form, as an upper electrode UE, the upper electrodes UE1 to UE3 of the display elements 201 to 203.

The evaporation chamber 136 is configured to form, as a first transparent layer TL1, the first transparent layers TL11 to TL31 of the display elements 201 to 203.

The evaporation chamber 137 is configured to form, as a second transparent layer TL2, the second transparent layers TL12 to TL32 of the display elements 201 to 203.

The post-processing portion 100F is configured to form the sealing layers SE1 to SE3 of the display elements 201 to 203.

For example, when a display element 201 comprising a tandem configuration is formed, the vapor deposition of the material for the processing substrate SUB is stopped in the evaporation chambers 124-2, 124-3, 131-2 and 131-3.

When a display element 202 comprising a tandem configuration is formed, the vapor deposition of the material for the processing substrate SUB is stopped in the evaporation chambers 124-1, 124-3, 131-1 and 131-3.

When a display element 203 comprising a tandem configuration is formed, the vapor deposition of the material for the processing substrate SUB is stopped in the evaporation chambers 124-1, 124-2, 131-1 and 131-2.

When a display element 201 comprising a single configuration is formed, the vapor deposition of the material for the processing substrate SUB is stopped in each of the evaporation chambers 124-2 to 131-3.

When a display element 202 comprising a single configuration is formed, the vapor deposition of the material for the processing substrate SUB is stopped in the evaporation chamber 124-1 and each of the evaporation chamber 124-3 to the evaporation chamber 131-3.

When a display element 203 comprising a single configuration is formed, the vapor deposition of the material for the processing substrate SUB is stopped in the evaporation chamber 124-1, the evaporation chamber 124-2 and each of the evaporation chamber 125 to the evaporation chamber 131-3.

According to the manufacturing device 100 comprising the above structure, effects similar to those of the manufacturing device shown in FIG. 19 are obtained. In addition, the manufacturing device 100 can form each of the display elements 201 to 203. Further, the manufacturing device 100 can easily form both a display element comprising a single configuration and a display element comprising a tandem configuration.

In the embodiment described above, each of the light emitting layers EM1, EM11 and EM12 corresponds to a first light emitting layer. Each of the light emitting layers EM2, EM21 and EM22 corresponds to a second light emitting layer. Each of the light emitting layers EM3, EM31 and EM32 corresponds to a third light emitting layer.

As explained above, the present embodiment can provide a manufacturing device of a display device such that the reduction in the production efficiency can be prevented.

All of the manufacturing devices that can be implemented by a person of ordinary skill in the art through arbitrary design changes to the manufacturing device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiment by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiment and are self-explanatory from the descriptions of the specification or can be arbitrarily conceived by a person of ordinary skill in the art are considered as the effects of the present invention as a matter of course.

What is claimed is:

1. A manufacturing device of a display device, the manufacturing device comprising:
a conveyance mechanism for conveying a processing substrate in a first direction, the processing substrate comprising a lower electrode located above a substrate, a rib comprising an aperture overlapping the lower electrode, and a partition which includes a lower portion located on the rib and an upper portion located on the lower portion and protruding from a side surface of the lower portion;
a preprocessing portion which is connected to an upstream side in the first direction of the conveyance mechanism and performs preprocessing for the processing substrate;
a post-processing portion which is connected to a downstream side in the first direction of the conveyance mechanism and performs post-processing for the processing substrate; and
first, second, third and fourth evaporation portions arranged in order in the first direction of the conveyance mechanism, wherein
the first evaporation portion comprises a plurality of evaporation chambers for forming an organic layer on the lower electrode in the aperture,
the second evaporation portion comprises an evaporation chamber for forming an upper electrode on the organic layer,
the third evaporation portion comprises an evaporation chamber for forming a first transparent layer on the upper electrode, and
the fourth evaporation portion comprises an evaporation chamber for forming a second transparent layer having a refractive index less than a refractive index of the first transparent layer on the first transparent layer.

2. The manufacturing device of claim 1, wherein
the preprocessing portion comprises:
a first load lock chamber in which the processing substrate is carried;
a baking portion which performs a process of drying the processing substrate carried in the preprocessing portion;
a plasma processing portion which reforms a surface of the lower electrode; and
a securing portion which secures the processing substrate to a carrier, and
the conveyance mechanism is configured to convey the carrier to which the processing substrate is secured in the first direction.

3. The manufacturing device of claim 2, wherein
the post-processing portion comprises:
a detachment portion which detaches the processing substrate from the carrier;
a first deposition portion which forms a first inorganic insulating layer on the second transparent layer;
an etching portion which reduces a thickness of the first inorganic insulating layer by performing anisotropic dry etching for the first inorganic insulating layer;
a second deposition portion which forms a second inorganic insulating layer on the first inorganic insulating layer; and
a second load lock chamber out of which the processing substrate is carried, and
a conveyance path of the processing substrate from the first load lock chamber to the second load lock chamber is maintained as a vacuum.

4. The manufacturing device of claim 3, wherein
the conveyance mechanism is configured to convey the carrier which has been detached from the processing substrate in the detachment portion in a second direction which is an opposite direction of the first direction.

5. The manufacturing device of claim 4, wherein
the conveyance mechanism comprises a first rail for conveying the carrier to which the processing substrate is secured in the first direction, and a second rail for conveying the carrier detached from the processing substrate in the second direction.

6. The manufacturing device of claim 1, wherein
the first evaporation portion comprises:
an evaporation chamber for forming a hole injection layer;
an evaporation chamber for forming a hole transport layer;
an evaporation chamber for forming an electron blocking layer;
an evaporation chamber for forming a light emitting layer;
an evaporation chamber for forming a hole blocking layer;
an evaporation chamber for forming an n-type charge generation layer;
an evaporation chamber for forming a p-type charge generation layer;
an evaporation chamber for forming an electron transport layer; and
an evaporation chamber for forming an electron injection layer.

7. The manufacturing device of claim 1, wherein
the first evaporation portion comprises:
an evaporation chamber for forming a hole injection layer;
an evaporation chamber for forming a hole transport layer;
an evaporation chamber for forming an electron blocking layer;
an evaporation chamber for forming a first light emitting layer;
an evaporation chamber for forming a second light emitting layer which emits light having a wavelength different from a wavelength of the first light emitting layer;
an evaporation chamber for forming a third light emitting layer which emits light having a wavelength different from the wavelengths of the first light emitting layer and the second light emitting layer;
an evaporation chamber for forming a hole blocking layer;
an evaporation chamber for forming an n-type charge generation layer;
an evaporation chamber for forming a p-type charge generation layer;
an evaporation chamber for forming an electron transport layer; and
an evaporation chamber for forming an electron injection layer.

8. The manufacturing device of claim 2, wherein
the securing portion comprises a mechanism for perpendicularly raising the processing substrate conveyed horizontally.

9. The manufacturing device of claim 8, wherein
the securing portion is connected to the conveyance mechanism.

10. The manufacturing device of claim 9, wherein
the first evaporation portion comprises an evaporation chamber for forming a hole injection layer as part of the organic layer at a position adjacent to the securing portion.

11. The manufacturing device of claim 3, wherein
the detachment portion is connected to the conveyance mechanism.

12. The manufacturing device of claim 11, wherein
the detachment portion comprises a mechanism for horizontally laying down the processing substrate conveyed perpendicularly.

13. The manufacturing device of claim 12, wherein
the fourth evaporation portion is adjacent to the detachment portion.

14. A manufacturing device of a display device, the manufacturing device comprising:
a conveyance mechanism for conveying a processing substrate comprising a lower electrode in a first direction;
a preprocessing portion which is connected to an upstream side in the first direction of the conveyance mechanism and performs preprocessing for the processing substrate;
a post-processing portion which is connected to a downstream side in the first direction of the conveyance mechanism and performs post-processing for the processing substrate; and
a plurality of evaporation chambers arranged in order in the first direction of the conveyance mechanism, wherein
the preprocessing portion comprises a securing portion which secures the processing substrate to a carrier,
the post-processing portion comprises a detachment portion which detaches the processing substrate from the carrier,
the securing portion is adjacent to, of the plurality of evaporation chambers, the evaporation chamber located at an end of the upstream side in the first direction, and
the detachment portion is adjacent to, of the plurality of evaporation chambers, the evaporation chamber located at an end of the downstream side in the first direction.

15. The manufacturing device of claim 14, wherein
the plurality of evaporation chambers include evaporation chambers for forming an organic layer, an upper electrode, a first transparent layer and a second transport layer having a refractive index less than a refractive index of the first transparent layer, respectively.

16. The manufacturing device of claim 15, wherein
the securing portion is adjacent to, of the plurality of evaporation chambers, the evaporation chamber for forming a hole injection layer as part of the organic layer.

17. The manufacturing device of claim 15, wherein
the detachment portion is adjacent to, of the plurality of evaporation chambers, the evaporation chamber for forming the second transparent layer.

18. The manufacturing device of claim 14, wherein
the plurality of evaporation chambers comprise, between the securing portion and the detachment portion:
an evaporation chamber for forming a first light emitting layer;
an evaporation chamber for forming a second light emitting layer which emits light having a wavelength different from a wavelength of the first light emitting layer; and
an evaporation chamber for forming a third light emitting layer which emits light having a wavelength different from the wavelengths of the first light emitting layer and the second light emitting layer.

19. A manufacturing device of a display device, the manufacturing device comprising:
a conveyance mechanism for conveying a processing substrate comprising a lower electrode in a first direction;
a preprocessing portion which is connected to an upstream side in the first direction of the conveyance mechanism and performs preprocessing for the processing substrate;
a post-processing portion which is connected to a downstream side in the first direction of the conveyance mechanism and performs post-processing for the processing substrate; and
a plurality of evaporation chambers arranged in order in the first direction of the conveyance mechanism, wherein
the preprocessing portion comprises a securing portion which secures the processing substrate to a carrier,
the post-processing portion comprises a detachment portion which detaches the processing substrate from the carrier, and
the plurality of evaporation chambers comprise, between the securing portion and the detachment portion:
an evaporation chamber for forming a first light emitting layer;
an evaporation chamber for forming a second light emitting layer which emits light having a wavelength different from a wavelength of the first light emitting layer; and
an evaporation chamber for forming a third light emitting layer which emits light having a wavelength different from the wavelengths of the first light emitting layer and the second light emitting layer.

20. The manufacturing device of claim 19, wherein
the securing portion is adjacent to, of the plurality of evaporation chambers, the evaporation chamber for forming a hole injection layer.
